(19) United States
(12) Patent Application Publication
(10) Pub. No.: US 2008/0314429 A1
(43) Pub. Date: Dec. 25, 2008

(54) Method for Thermal Matching of a Thermoelectric Generator with a Heat Source Having High Thermal Resistance and Thermoelectric Generator thus Obtained

(75) Inventor: Vladimir Leonov, Leuven (BE)

Correspondence Address: MCDONNELL BOEHNEN HULBERT & BERGHOFF LLP, 300 S. WACKER DRIVE, 32ND FLOOR, CHICAGO, IL, 60606, US

(73) Assignee: STICHTING IMEC NEDERLAND, Eindhoven (NL)

(21) Appl. No.: 12/028,614

(22) Filed: Feb. 8, 2008

Related U.S. Application Data
(60) Provisional application No. 60/889,112, filed on Feb. 9, 2007.
(60) Provisional application No. 60/967,864, filed on Sep. 7, 2007.

(51) Int. Cl. H01L 35/34; H01L 35/28

(52) U.S. Cl. 136/201; 136/225

(57) ABSTRACT

The present disclosure relates to thermoelectric generators (TEGs) and more specifically to TEGs operated with a heat source having a high thermal resistance, more specifically to TEGs operated under conditions of non-constant heat flow and non-constant temperature difference between a hot plate and a cold plate. A thermoelectric generator for connection between a heat source and a heat sink comprises a thermopile unit, the thermopile unit comprising at least one thermopile stage, each thermopile stage comprising a number of thermocouples each having a couple of thermocouple legs, the thermocouple legs being provided in between a hot junction plane and a cold junction plane. The number of thermocouples in the thermoelectric generator is such that the thermal resistance (R_{TEG}) of the thermoelectric generator between the hot junction plane of the thermopile stage comprising the hottest junctions and the cold junction plane of the thermopile stage comprising the coldest junction is near the value calculated as the thermal resistance of the ambient (R_{amb}), multiplied by the parasitic thermal resistance (R_{TEG,0}), divided by the sum of the parasitic thermal resistance R_{TEG,0} and twice the thermal resistance of the ambient (R_{amb}).

This application claims the priority of U.S. Provisional Patent Application No. 60/889,112, filed Feb. 9, 2007, and of U.S. Provisional Patent Application No. 60/967,864, filed Sep. 7, 2007.

### BACKGROUND

The present disclosure relates to thermoelectric generators (TEGs).

A thermoelectric generator (TEG) utilises a temperature difference occurring between a relatively hot (warm) object, i.e. a heat source, and its colder surrounding, i.e. a heat sink, and is used to transform a consequent heat flow into a useful electrical power. The necessary heat can, for example, be produced by radioactive materials, as e.g. in space applications, or by sources available in the ambient, like standard cooling/heating systems, pipe lines including pipe lines with warm waste water, surfaces of engines, parts of machines and buildings or by homeotherms (i.e. warm-blooded animals or human beings). Natural temperature gradients can be used as well as geothermal temperature gradients, temperature gradients on ambient objects when naturally cooling/heating at night/day, temperature differences between a liquid or a gas in a pipeline and its surrounding, heated machinery, engines, transport and ambient air, between window glass and air indoor or outdoor, etc.

There is an increasing interest in miniaturised TEGs, which could replace batteries in consumer electronic products operating at low power. For example, TEGs mounted in a wristwatch have been used to generate electricity from wasted human heat, thus providing a power source for the watch itself. See M. Kishi, H. Nemoto, T. Hamao, M. Yamamoto, S. Sudou, M. Mandai and S. Yamamoto in “Micro-Thermoelectric Modules and Their Application to Wristwatches as an Energy Source”, Proceedings ICT'99 18th Int. Conference on Thermoelectrics (1999), pp. 301-307 (Seiko Instruments).

MEMS technology has been used to fabricate miniaturised TEGs, as described by M. Strasser, R. Aigner, C. Lauterbach, T. F. Sturm, M. Franosch and G. Wachutka in “Micromachined CMOS Thermoelectric Generators as On-chip Power Supply”, Transducers '03, 12th International Conference on Solid State Sensors, Actuators and Microsystems (2003), pp. 45-48 (Infineon Technologies); by A. Jacquot, W. L. Liu, G. Chen, J.-P. Fleurial, A. Dausher, B. Lenoir in “Fabrication and modeling of an in-plane thermoelectric micro-generator”, Proceedings ICT '02, 21^{st} International Conference on Thermoelectrics (2002), pp. 561-564; and by H. Böttner, J. Nurnus, A. Gavrikov, G. Kühner, M. Jagle, C. Künzel, D. Eberhard, G. Plescher A. Schubert and K.-H. Schlereth in “New Thermoelectric Components using Microsystem Technologies”, Journal of Microelectromechanical Systems, vol. 13 (2003), no. 3, pp. 414-420.

Thin film technology has also been used to fabricate miniaturised TEGs on a thin polymer tape, as described by S. Hasebe, J. Ogawa, M. Shiozaki, T. Toriyama, S. Sugiyama, H. Ueno and K. Itoigawa in “Polymer based smart flexible thermopile for power generation”, 17th IEEE Int. Conf. Micro Electro Mechanical Systems (MEMS) (2004), pp. 689-692; by I. Stark and M. Stordeur in “New micro thermoelectric devices based on bismuth telluride-type thin solid films”, Proceedings of the 18th International Conference on Thermoelectrics (ICT), Baltimore (1999), pp. 465-472; by Ingo Stark and P. Zhou in WO 2004/105143 A1; by Ingo Stark in U.S. Pat. No. 6,958,443, and by I. Stark in “Thermal Energy Harvesting with Thermo Life®”, Proceedings of International Workshop on Wearable and Implantable Body Sensor Networks (BSN'06), 2006.

In US 2006/0000502, a micromachined TEG is proposed that is specially suited for application on heat sources having a large thermal resistance, e.g., on homeotherms. The design and technology for micromachined thermopiles specially suited for such applications are reported by V. Leonov, P. Fiorini, S. Sedky, T. Torfs and C. Van Hoof in “Thermoelectric MEMS generators as a power supply for a body area network”, Proceedings of the 13th International Conference on Solid-State Sensors, Actuators and Microsystems (Transducers'05) (2005), pp. 291-294.

TEGs can be characterised by an electrical and a thermal resistance and by both voltage and power generated per unit temperature difference between the hot and cold sides of the TEG. The relative importance of these factors depends on the specific application. In general, electrical resistance is preferably low and, obviously, voltage or power output are preferably maximised (in particular in applications with small temperature difference, e.g. a few degrees C. or a few tens of degrees C.). If a constant temperature difference is imposed at the boundaries of the TEG, e.g. by means of hot and cold plates at fixed temperatures relative to each other, the value of thermal resistance is not crucial, because the output voltage and the output power are proportional to the temperature difference, which is fixed. However, if the boundary condition is a constant heat flow or a limited heat flow through the device, then the thermal resistance, on one hand, needs to be large enough to generate a reasonable temperature drop over the device, but on the other hand, needs to be small enough to avoid a drastic decrease in the heat flow through the TEG, for example by more than a factor of 2. The term “constant heat flow” means that in the considered range of TEG thermal resistances the heat flow through the device is substantially constant (limited by the ambient). However, this does not mean that the heat flow stays at the same value over time in a practical application. The term “limited heat flow” means that when decreasing the thermal resistance of the TEG, the heat flow through the device increases until a certain value, at which the conditions of constant heat flow are reached. In the case of “limited heat flow” the heat flow through the device is not limited by the ambient, but for example by the thermal resistance of the TEG.

The basic element of a TEG is a thermocouple 10 (FIG. 1). An example of a thermocouple 10 comprises a first leg 11 and a second leg 12 formed of two different thermoelectric materials, for example, of the same but oppositely doped semiconductor material and exhibiting low thermal conductance and low electrical resistance. For example, the legs 11, 12 could be formed from BiTe. If the first leg 11 is formed of n-type BiTe, then the second leg 12 may be formed of p-type BiTe, and vice versa. The legs 11, 12 are connected by an electrically conductive interconnect, e.g. a metal layer interconnect 13, which forms a low-resistance ohmic contact to the semiconductor legs 11, 12, thus forming a junction between the semiconductor legs 11,12.

In FIG. 2, a TEG 20 comprising a thermopile 21 comprising a plurality, preferably a large number, of thermocouples 10, is shown where the junctions between legs 11, 12 are located in two planes: a hot junction plane 24 and a cold junction plane 25. The thermopile 21 is sandwiched in between a hot plate 22 and a cold plate 23. The hot plate 22 and the cold plate 23 are made of materials having a large thermal conductivity, so that the thermal conductance of the plates 22, 23 is much larger (at least a factor of 10) than the total thermal conductance of the thermopile 21.

In case of a constant or limited heat flow through the TEG 20, the output voltage and power depend on the number of thermocouples 10 comprised in it. It can easily be shown that in the case of constant heat flow, the maximum power is obtained when the heat flow through the thermoelectric material is equal to the “parasitic” heat exchange between the hot plate 22 and the cold plate 23 through the air, including radiation heat exchange.

In order to give numerical example of the above case of constant heat flow, the TEG device area may be fixed to 1 cm² and the heat flow is limited by a value of 18.5 mW/cm², which is about 3 times larger than the natural heat flow from human beings to the environment at indoor conditions. Such heat flow is obtainable using the design of the TEG 40 according to US 2006/0000502, as depicted in FIGS. 3 to 6, with a micromachined thermopile 31 between a hot die 45 featured with a pillar/rim structure and a cold die 46, provided with a spacer 41 to increase the distance in between the two plates 37, 38. Different embodiments may be provided for the hot and cold plates 37, 38: using a large hot plate 37 and a large cold plate 38 (FIG. 4), or using a smaller hot plate 37 and a larger cold plate 38 (FIG. 5). The cold plate 38 can also be folded or shaped as a radiator 48 of more complex shapes, e.g. as shown in FIG. 6 for a multi-fin radiator case. Furthermore, in the numerical example, it is assumed that the legs 11, 12 of the thermocouples 10 are made of respectively n- and p-type BiTe, and that the TEG 20 operates in air. The thermal resistance of the metal layer interconnect 13 and the electrical resistance of the contacts between the legs 11, 12 of the thermocouple 10 and the metal layer interconnect 13 are considered to be negligible. Values used for the calculations of TEG performance in the numerical example are reported in Table I herein below:

TABLE I

| | |
|---|---|
| Thermal conductivity of BiTe, W m⁻¹ K⁻¹ | 1.5 |
| Thermal conductivity of air, W m⁻¹ K⁻¹ | 0.026 |
| Resistivity of BiTe (n and p), Ω m | 10⁻⁵ |
| Input heat flow, W m⁻² | 185 |

First, a commercial TEG 20 is considered. Dimensions chosen for the legs 11, 12 are close to those of high quality commercial devices, e.g. with a lateral size a of 0.25 mm, the lateral size a being defined as the square root of the cross-section of the legs, and a height h of 0.75 mm (FIG. 1). In FIG. 7, the output power Pₒᵤₜ (solid line) and output voltage Vₒᵤₜ (dashed line) for such a TEG 20 are illustrated as a function of the number of thermocouples 10. At maximum power, the output voltage is low, e.g. 15 mV, as can be seen from FIG. 7, which is well below the level necessary for powering standard electronics. Typical voltages needed are 3 to 5 V. It is straightforward to up-convert for example 800 mV to these values, however, it is much more difficult and less efficient to reach these values starting from 300 mV or lower.

As can be seen in FIG. 8, the temperature drop corresponding to the maximum power is about 2.3 K. The performance of the TEG 20 can be improved by increasing the aspect ratio of the legs 11, 12. For example, as described by Seiko (M. Kishi, H. Nemoto, T. Hamao, M. Yamamoto, S. Sudou, M. Mandai and S. Yamamoto in “Micro-Thermoelectric Modules and Their Application to Wristwatches as an Energy Source”, Proceedings ICT'99 18th International Conference on Thermoelectrics, p. 301-307, 1999), the lateral size a and height h of the legs 11, 12 are respectively 0.08 mm and 0.6 mm. In this case, a 0.4 cm² TEG (10 units of 2×2 mm² size each are used in the watch described) gives a voltage of 0.15 V when it delivers a maximum power of about 0.022 mW on a load. Although the state-of-the-art aspect ratio h/a of the thermoelectric legs 11, 12 of 7.5 (=0.6 mm/0.08 mm) in the above example represents a current technological limit, the voltage obtained is still of impractical use. It can thus be concluded that the low output voltage is the main restriction to a wide use of standard TEGs 20 operated in a low heat flow mode, which is for example the case with heat sources such as industrial sources of wasted heat or pipelines, walls, machinery or homeotherms.

Next, a micromachined TEG 20 is considered which comprises legs with a thickness of 0.5 μm, a width of 1 μm and a height of 5 μm. In FIG. 9, the output power (∘) and voltage (▴) are shown as a function of the number of thermocouples 10. The power is limited to only 0.00011 mW. This maximal power is achieved for a TEG 20 comprising about 1.8 million thermocouples 10 (see FIG. 9). For the same number of thermocouples 10, a voltage of about 3V is obtained. In FIG. 10, the temperature difference (∘) between the hot and the cold plates (22, 23) and the electrical resistance (▴) of a micromachined TEG 20 are reported. The temperature difference (∘) between the hot and the cold plates of the TEG 20 at the maximal power is limited to 18 mK. The corresponding thermal resistance, which is determined by Rₜₕ=ΔT/P (with ΔT=the temperature difference between the hot and cold plates and P the heat flow) is 1 K/W for a 1 cm² device, which is not enough to obtain a good temperature drop (e.g. several tens percent of the available temperature difference between the heat source and the heat sink). The above results are confirmed by experimental data. For example, as described by Infineon, a large number of thermocouples 10 have been fabricated and a large output voltage is obtained. See (M. Strasser, R. Aigner, C. Lauterbach, T. Sturm, M. Franosch and G. Wachutka, “Micromachined CMOS Thermoelectric Generators as On-chip Power Supply”, Transducers '03, 12^{th} International Conference on Solid State Sensors, Actuators and Microsystems (2003), p. 45-48. H. Bottner, A. Schubert, K. Schlereth, D. Eberhard, A. Gavrikov, M. Jagle, G. Kühner, C. Künzel, J. Nurnus and G. Plescher point out in “New Thermoelectric Components using Micro-System-Technologies”, ETS 2001-6th European Workshop on Thermoelectrics (2001), that both the temperature drop and the output power are low in micromachined TEGs 20. For example, micromachined TEGs produced by Infineon show about 10 mK temperature difference between the hot and the cold side. See H. Bottner in “Thermoelectric Micro Devices: Current State, Recent Developments and future Aspects for Technological Progress and Applications”, Proceedings of the 21^{st} International Conference on Thermoelectrics (2002), p. 511-518.

For the number of thermocouples 10 at which the maximum power is achieved (see FIG. 9), the electrical resistance approaches 0.4 GΩ (see FIG. 10), which is a too high value to be efficient, e.g. for a generator powering electronic devices or battery chargers. It can be seen that the optimal number of thermocouples 10 is about 1.8 million. A TEG device with an area of 1 cm² and with this large number of thermocouples 10 can be fabricated if one thermocouple 10 occupies a square of only about 7×7 μm² size. This is a difficult but not impossible task. The large number of thermocouples 10 furthermore has the drawback of increased probability of getting a non-functioning device, since thermocouples 10 are electrically coupled in series. Hence, the failure of one thermocouple 10 will cause the failure of the whole TEG 20. This drawback potentially leads to a dramatically decreased yield of good devices and increased cost of manufacturing.

A thermal analysis of the TEG 20 as illustrated in FIG. 2 is performed and analytical results are reported and discussed hereinafter. It is assumed that the hot plate 22 and the cold plate 23 are of equal size. The number of thermocouples n, the temperature drop ΔT and the output voltage Vₒᵤₜ at a maximal power Pₒᵤₜ are given by the expressions (1) to (4):

$$\begin{matrix}n = \frac{{G}_{air} h}{{g}_{te} {a}^{2}} = \frac{{Ag}_{a}}{{g}_{te} {a}^{2}} , & ( 1 ) \\ {P}_{out} = \frac{1}{16} {S}^{2} \frac{{W}_{u}^{2} {A}^{2}}{{g}_{te} ρ} \frac{1}{{G}_{air}} = \frac{1}{16} {S}^{2} \frac{{W}_{u}^{2} A}{{g}_{te} ρ} \frac{h}{{g}_{a}} , & ( 2 ) \\ Δ T = \frac{{W}_{u} A}{2 {G}_{air}} = \frac{{W}_{u} h}{2 {g}_{a}} , & ( 3 ) \\ {V}_{out} = \frac{{W}_{u} AS}{2 {g}_{te}} \frac{h}{{a}^{2}} , & ( 4 )\end{matrix}$$

wherein A is the area of the hot/cold plate 22, 23,
a is the lateral size of the legs 11, 12, being defined as the square root of the cross-section of the legs,
h is the height of the legs 11, 12 (as indicated in FIG. 1),
gₐ is the thermal conductivity of air,
gₜₑ is the thermal conductivity of the thermoelectric material the legs 11, 12 are made of,
ρ is the resistivity of the thermoelectric material the legs 11, 12 are made of,
S is the Seebeck coefficient (assumed to be equal for both legs 11, 12),
Gₐᵢᵣ is the thermal conductance of the air between the hot plate 22 and the cold plate 23,
Wᵤ is the fixed heat flow per unit area.

Equation (1) and (2) show that, at the maximum power condition the number n of necessary thermocouples and the output voltage depend on the ratio h/a². It can then be stated that micromachined thermoelectric generators require a larger number of thermocouples and deliver power at a larger voltage than non-micromachined generators. The power Pₒᵤₜ and temperature difference ΔT (resp. equation (2) and (3)) depend mainly on the thermal conductance Gₐᵢᵣ of the air between the hot plate and the cold plate. Since this thermal conductance Gₐᵢᵣ is large for micromachined thermopiles, the temperature drop ΔT and power Pₒᵤₜ are low for these devices.

The performance of the micromachined TEG according to US 2006/0000502 as illustrated in FIGS. 3 to 6 is described by the following formulas:

$$\begin{matrix}n = \frac{{G}_{air}}{[ \frac{{g}_{a} {b}^{2} + {g}_{te} {a}^{2}}{h} ]} & ( 5 ) \\ {P}_{out} = \frac{1}{16} {S}^{2} \frac{{W}_{u}^{2} {A}^{2}}{ρ} \frac{1}{{G}_{air}} \frac{1}{{g}_{te} + \frac{{b}^{2}}{{a}^{2}} {g}_{a}} & ( 6 ) \\ {V}_{out} = S \frac{{W}_{u} A}{2} [ \frac{h}{{g}_{a} {b}^{2} + {g}_{te} {a}^{2}} ] & ( 7 )\end{matrix}$$

wherein b is the lateral size of the plates 32, 33 corresponding to a basic element 30, as indicated in FIG. 3.

It may be noticed that expression (5) for the number of thermocouples 10 at maximal power and expression (6) for the maximal power are similar to expressions (1) and (2), however, according to US 2006/0000502, Gₐᵢᵣ is small. As a consequence, the number of thermocouples 10 to obtain the maximal power is reduced, while the maximal power is increased. The expression (7) of the output voltage at maximal power is similar to expression (4); it mainly depends on the dimensions of the thermocouples 10.

As an example, an optimization of a commercial TEG is performed below by modelling of the thermopile having a leg size that is the same as used in a prior art Seiko thermocouple, i.e. with h=0.6 mm and a=0.08 mm, FIG. 1, where each leg occupies 0.2×0.2 mm² area on the chip. Calculations are performed for a 1×1 cm² chip size, i.e. larger than used in Seiko thermopiles, in order to reach prior art matching conditions, i.e. when the thermal resistance of the thermopile is equal to the thermal resistance of the air in between the two plates. The calculations are performed for the following conditions: the source temperature Tₛ inside the human body, i.e. the core temperature, is 37° C., the environmental temperature of ambient air, T_{amb}, is 22° C., the thermal resistance of the body R_{th,sorce}=300 cm²K/W, the contact area of the device with the skin is 1 cm², and the distance between the hot and the cold plates is 0.6 mm. The material parameters used for the modelling are reported in Table I. The prior art method of optimizing is in finding a condition of equality of the thermal conductance through the air to the thermal conductance through the thermopile leg material, giving the optimal number of thermocouples corresponding to the maximal power generated. The output power is plotted in FIG. 11 versus the ratio of the thermal resistance of the thermopile leg material R_{th,tp} to the parasitic thermal resistance of the air R_{th,air, in} (each ratio corresponding to a different number of thermocouples) and is found to obey equations (1)-(4).

Optimizing a micromachined thermopile according to the prior art is performed next for a TEG 20 using the following dimensions of the legs 11, 12: h=0.005 mm and a=0.001 mm, where each leg occupies 0.01×0.005 mm². The calculations are performed at Tₛ=37° C., T_{amb}=22° C., the thermal resistance of the body R_{th,source}=300 cm²K/W, contact area of the device with the skin is 1 cm² and the two plates are 1 cm² each, the distance between the hot and the cold plates is 0.005 mm. The material parameters used for the modelling are reported in Table I hereinabove. Results are shown in FIG. 12.

Optimizing a micromachined TEG 40 (FIGS. 3 to 6) fabricated according to US 2006/0000502 when the thermopiles are being positioned on a spacer 41, is performed next. According to the state of the art, the matching conditions can be found using equations (5)-(7). The optimal number of thermocouples is then considered to occur at the same conditions as in the above two examples, i.e. when the thermal conductance through the air in between the hot and cold plates is equal to the thermal conductance through the thermopile leg material. However, when the results are plotted, see FIG. 13, the plot shows a distinct mismatch of the optimal power to the condition of the equality of the thermal conductance through the air to the thermal conductance through the thermopile leg material, and true matching conditions should be found to make the TEG generate the maximal power. It is pointed out that the thermal resistance of the heat source and the heat sink as seen in equations (1)-(7), does not affect the result of the TEG 20 and TEG 40 optimization according to the prior art.

According to US 2006/0000502, the ratio of thermal resistance R_{th,tp} between the hot and cold junctions of the thermopile to the thermal resistance R_{th,source-sink} between the heat source and the heat sink (hot plate 37 and cold plate 38 as illustrated in FIGS. 3 to 6) is an important property of the thermal design of a TEG for application on a heat source with large thermal resistance. This is of lesser importance when the thermopile is used under condition of a constant temperature difference between the hot plate and the cold plate. However, this becomes important in case of constant or limited heat flow especially in case of application of the TEG on a heat source with large thermal resistance when the heat flow is varied depending on the thermal resistance of the thermopile.

### SUMMARY

It is an aim of the present disclosure to provide thermoelectric generators (TEGs), more specifically TEGs operated under conditions of non-constant heat flow and non-constant temperature difference, with good output power. More specifically, the present disclosure provides a method for thermal matching of such a TEG with its heat source and its heat sink. Furthermore, it is an aim of the present disclosure to provide a design method for thermal matching of a thermoelectric generator operated under conditions of non-constant heat flow and non-constant temperature difference with its heat source and its heat sink.

In one embodiment, a thermoelectric generator for connection between a heat source and a heat sink comprises a thermopile unit, the thermopile unit comprising at least one thermopile stage, each thermopile stage comprising a number of thermocouples each having a couple of thermocouple legs, the thermocouple legs being provided in between a hot junction plane and a cold junction plane. The number of thermocouples in an exemplary thermoelectric generator is such that the thermal resistance (R_{TEG}) of the thermoelectric generator between the hot junction plane of the thermopile stage comprising the hottest junctions and the cold junction plane of the thermopile stage comprising the coldest junctions does not deviate more than 50%, preferably not more than 20%, more preferred not more than 10%, still more preferred not more than 5% from the thermal resistance of the ambient (R_{amb}), being the sum of the thermal resistance of the heat source, the thermal resistance of the heat sink and the thermal resistance of all parts of the thermoelectric generator serially coupled to the at least one thermopile stage, multiplied by the parasitic thermal resistance (R_{TEG,0}) between the hot junction plane of the thermopile stage comprising the hottest junctions and the cold junction plane of the thermopile stage comprising the coldest junctions for a same thermoelectric generator but comprising no thermocouples or only one thermocouple leg, this product being divided by the parasitic thermal resistance (R_{TEG,0}) between the hot junction plane of the thermopile stage comprising the hottest junctions and the cold junction plane of the thermopile stage comprising the coldest junctions for a same thermoelectric generator but comprising no thermocouples or only one thermocouple leg, summed with twice the thermal resistance of the ambient (R_{amb}).

In some embodiments, the product of R_{amb} and R_{TEG,0} may be divided by the sum of R_{TEG,0} and twice the thermal resistance of the ambient, R_{amb,0}, for a same thermoelectric generator but comprising no thermocouples or only one thermocouple leg. This is the case when the thermal resistance of the ambient is constant (i.e. R_{amb}=R_{amb,0}) or when R_{TEG,0} is substantially larger than R_{amb} and substantially larger than R_{amb,0}.

At least one thermopile stage may comprise a first plate thermally connected to the junctions in the hot junction plane of that thermopile stage and/or a second plate thermally connected to the junctions in the cold junction plane of that thermopile stage.

The thermopile unit may be thermally connected to and positioned in between a hot plate for connection to the heat source and a cold plate for connection to the heat sink. The thermoelectric generator may furthermore comprise a radiator mounted on or placed instead of the cold plate.

The surface area of the hot plate may be larger than the area of the thermopile unit, the area of the thermopile unit being determined in a plane parallel to the hot plate, and/or the surface area of the cold plate may be larger than the area of the thermopile unit, the area of the thermopile unit being determined in a plane parallel to the cold plate, so as to obtain a better thermal matching. The area of the thermopile unit may be determined by a perpendicular projection of the thermopile unit onto the hot or cold plate.

A thermoelectric generator may further comprise at least one thermally conductive spacer between the at least one thermopile stage and the hot plate and/or the cold plate and/or between two of the thermopile stages. The presence of the at least one thermally conductive spacer may cause improvement of the Rayleigh number or Reynolds number of the heat transfer at the surface of the cold plate or at the surface of the radiator, as compared with the same thermoelectric generator without a thermally conductive spacer.

The thermopile unit may comprise more than one thermopile stage, thus improving the Rayleigh number or Reynolds number of the heat transfer at the surface of the cold plate or at the surface of the radiator as compared with the same thermoelectric generator comprising a thermopile unit with one thermopile stage.

The thermoelectric generator may further comprise at least one heat-spreading chip between the at least one thermopile stage and the hot plate and/or the cold plate and/or between two of the thermopile stages.

The thermoelectric generator may further comprise a shock-protecting structure. The shock-protecting structure may for example comprise a thermally isolating plate with pillars from thermally isolating material connected to the cold plate. The thermoelectric generator may further comprise a touch-protecting structure.

The thermoelectric generator may further comprise a thermal reflector positioned in between the hot plate and the cold plate, the thermal reflector covering the hot plate, the cold plate, the radiator, the first plate and/or the second plate and being thermally isolated therefrom.

The thermoelectric generator may be attached to a wrist strap, a head strap, a strap for animals or may be embedded into clothes and garments, a cap, a shoe, a belt, jewelery or a clamp for attaching to such objects. The thermoelectric generator may be supplied with additional heat transfer means mounted in a piece of clothing for being worn above or under garment in which said thermoelectric generator is embedded or attached. These heat transfer means may include heat-conductive threads or wires into the piece of clothing. The thermal interconnection of the thermoelectric generator and the heat transfer means may be performed magnetically using magnets and corresponding metal pieces in different layers of clothing.

The thermocouples used herein may be micromachined thermocouples.

The thermocouples may be positioned on a polymer tape or on a membrane, or thin/thick-film thermocouples without a substrate may be used.

At least one of the thermopile stages may comprise a thermally conductive structure forming a thermal interconnection between the thermocouple legs and at least one of the cold plate, the hot plate, and the radiator, the thermally conductive structure comprising a thin/thick film of thermally conductive material or a substrate material.

The thermoelectric generator may be filled at least partially with thermally isolating material. This thermally isolating material may for example be a micro- or sub-microporous material having a thermal conductivity less than the thermal conductivity of air or not exceeding the thermal conductivity of air by 50%.

The inner volume of the thermoelectric generator may be encapsulated on its perimeter between the hot plate and the cold plate or the radiator, using a layer of thermally isolating material. This layer of thermally isolating material may also serve as a shock-protecting structure.

The volume between the hot plate and the cold plate or the radiator may be filled with a gas having lower thermal conductivity than air or which is at a pressure that is lower than the atmospheric pressure.

In some embodiments, the inner surface of the hot plate or the inner surface of the reflector (the inner surface being the surface not facing the heat source) may have a low emissivity (lower than 20%, preferably lower than 10%) in the infrared region and the inner surface of the cold plate and the radiator (the inner surface being the surface not facing the heat sink) may have a high emissivity (higher than 90%, preferably higher than 95%) in the infrared region.

Further disclosed herein is a method for designing a thermoelectric generator for connection between a heat source and a heat sink and with a limited heat flow through the thermoelectric generator and a non-constant temperature difference between the heat source and the heat sink, where the thermoelectric generator comprises a thermopile unit. The thermopile unit comprises at least one thermopile stage, each thermopile stage including a number of thermocouples each having a couple of thermocouple legs, where the thermocouple legs are provided in between a hot junction plane and a cold junction plane. In such a method, the thermal resistance (R_{TEG}) is determined of the thermoelectric generator between the hot junction plane of the thermopile stage comprising the hottest junctions and the cold junction plane of the thermopile stage comprising the coldest junctions as a function of the number of thermocouples. The sum (R_{amb}) is determined of the thermal resistance of the heat source, the thermal resistance of the heat sink and the thermal resistance of all parts of the thermoelectric generator serially coupled to the at least one thermopile stage, as a function of the number of thermocouples. The parasitic thermal resistance (R_{TEG,0}) is determined between the hot junction plane of the thermopile stage comprising the hottest junctions and the cold junction plane of the thermopile stage comprising the coldest junctions for a same thermoelectric generator but comprising no thermocouples or only one thermocouple leg. The product of R_{amb} and R_{TEG,0} is divided by the sum of R_{TEG,0} and twice R_{amb}, resulting in a thermal resistance value. The number of thermocouples is adapted such that the thermal resistance (R_{TEG}) of the thermoelectric generator between the hot junction plane of the thermopile stage comprising the hottest junctions and the cold junction plane of the thermopile stage comprising the coldest junctions does not deviate more than 50%, preferably not more than 20%, more preferred not more than 10%, still more preferred not more than 5% from the thermal resistance value.

In certain embodiments, the product of R_{amb} and R_{TEG,0} may be divided by the sum of R_{TEG,0} and twice the thermal resistance of the ambient, R_{amb},O, for a same thermoelectric generator but comprising no thermocouples or only one thermocouple leg. This is the case when the thermal resistance of the ambient is constant (i.e. R_{amb}=R_{amb,0}) or when R_{TEG,0} is substantially larger than R_{amb} and substantially larger than R_{amb,0}.

The term “limited heat flow” means that when decreasing the thermal resistance of the TEG, the heat flow through the device increases until a certain value, at which the conditions of constant heat flow are reached. In the case of “limited heat flow” the heat flow through the device is not limited by the ambient, but for example by the thermal resistance of the TEG.

Embodiments of the method for designing a thermoelectric generator may furthermore comprise varying the shape and/or the size of a hot plate and/or a cold plate, wherein the thermopile unit is thermally connected to and positioned in between the hot plate for connection to the heat source and the cold plate for connection to the heat sink.

A method for designing a thermoelectric generator may further comprise providing at least one thermally conductive spacer in between the at least one thermopile stage and the hot plate and/or the cold plate and/or between two thermopile stages. The thermally conductive spacer may improve the Rayleigh number or Reynolds number of the heat transfer at the surface of the cold plate or at the surface of the radiator as compared with the same thermoelectric generator without said at least one thermally conductive spacer.

The method for designing a thermoelectric generator may further comprise providing a radiator mounted on or placed instead of the cold plate, and varying the size and/or the shape of the radiator.

The thermocouples may be positioned on a polymer tape or on a membrane, or thin/thick-film thermocouples without a substrate may be used.

Furthermore, the present disclosure provides a computer program product for executing a method for designing a thermoelectric generator. Also provided is a machine readable data storage device storing the computer program product. The present disclosure further provides for transmission of the computer program product over a local or wide area telecommunications network.

The thermoelectric generator may be used with an animal, a human being, a clothed human being or ambient air as a heat source and with ambient air, an animal, a human being or a clothed human being as a heat sink.

The thermoelectric generator may be used with a space object or an artificial space object as a heat source and interplanetary space, a space object or an artificial space object as a heat sink.

The thermoelectric generator may be used with a distant radiating object or a plurality of distant radiating objects like space objects or ambient objects on earth as a heat source.

These and other characteristics, features and advantages will become apparent from the following detailed description, taken in conjunction with the accompanying drawings, which illustrate, by way of example, the principles of the invention. This description is given for the sake of example only, without limiting the scope of the invention. The reference figures quoted below refer to the attached drawings.

### BRIEF DESCRIPTION OF THE DRAWINGS

FIG. 1 is a schematic illustration of a thermocouple comprising an n-type and a p-type semiconducting leg and conductive interconnects, e.g. metal layer interconnects.

FIG. 2 is a schematic illustration of a simple prior art TEG comprising a (large) number of thermocouples sandwiched in between a hot plate and a cold plate; the example illustrated only shows six thermocouples, but a TEG may comprise many more.

FIG. 3.a is a schematic illustration of a basic element according to US 2006/0000502 forming a thermopile chip.

FIG. 3.b is a schematic illustration of a thermopile chip according to US 2006/0000502, sandwiched between two plates.

FIG. 4 is a side view of an assembly of a micromachined thermopile chip and a micromachined heat-spreading chip with two plates and a spacer, according to US 2006/0000502.

FIG. 5 is another side view of an assembly of a micromachined thermopile chip and a micromachined heat-spreading chip with a spacer and a radiator according to US 2006/0000502.

FIG. 6 is a side view of an assembly of a micromachined thermopile chip and a micromachined heat-spreading chip with a spacer and a radiator according to US 2006/0000502.

FIG. 7 shows the output voltage (---) and the electrical output power (—) as a function of the number of thermocouples for a prior art BiTe TEG as illustrated in FIG. 2.

FIG. 8 shows the temperature difference between the hot and the cold sides as a function of the number of thermocouples for a prior art BiTe TEG as illustrated in FIG. 2.

FIG. 9 shows the output voltage (▴) and the electrical output power (∘) as a function of the number of thermocouples for a prior art micromachined BiTe TEG.

FIG. 10 shows the temperature difference (∘) between the hot and cold plates and the corresponding electrical resistance (▴) of a prior art micromachined BiTe TEG, as a function of the number of thermocouples.

FIG. 11 shows calculation results for the prior art thermal matching of a commercially available prior art TEG.

FIG. 12 shows calculation results for the prior art thermal matching of a prior art micromachined TEG.

FIG. 13 shows calculation results for the prior art thermal matching of a micromachined TEG according to US 2006/0000502.

FIG. 14 shows an embodiment of an exemplary TEG as disclosed herein.

FIG. 15 shows a thermopile unit of a TEG according to embodiments disclosed herein.

FIG. 16 shows a TEG with multi-stage thermopiles according to embodiments disclosed herein.

FIG. 17 shows another TEG with multi-stage thermopiles and thermal isolation according to embodiments disclosed herein.

FIG. 18 shows a TEG in accordance with embodiments disclosed herein on a human wrist, illustrating the effect of decoupling the Rayleigh/Reynolds numbers.

FIG. 19 shows a TEG with multi-stage thermopiles in accordance with embodiments disclosed herein on a human wrist and explains the effect of decoupling the Rayleigh/Reynolds numbers.

FIG. 20 shows the dependency of the output power on the ratio of the thermal resistance of the thermopile because of thermal conductance through the thermocouple legs to the thermal resistance of the air in between the cold and hot plates.

FIG. 21 shows the dependency of the output power and changes in the heat flow due to the presence of the TEG on the ratio of the temperature drop on the thermopile and the temperature drop occurring in the same TEG without the thermopile or with only one thermocouple leg of the same size in it.

FIG. 22 shows a TEG on a human arm with a thermal isolation sheet added to the garment.

FIG. 23 shows a waterproof watch-size wrist TEG with a cold plate and a protecting grid for outdoor use.

FIG. 24 shows a watch-size wrist TEG with a pin-featured radiator and a protecting grid for indoor use.

FIG. 25 shows open circuit voltages measured on a TEG.

FIG. 26 shows measurement results of the power transmitted into a matched load by a TEG.

FIG. 27 shows the difference of power matching (solid line) according to a prior-art approach (∘) and the matching according to embodiments disclosed herein (▴). The corresponding change of the heat flow is shown for the case of one-stage and multi-stage arrangement of the thermopiles (dotted and dashed lines, respectively). The horizontal arrows show the range of the power for a mismatched ten-stage TEG, where the power still exceeds the power obtainable using the prior art approach.

FIG. 28 shows power produced by a TEG in accordance with embodiments disclosed herein, for different numbers of thermopile stages versus the number of thermocouples per stage.

FIG. 29 shows the difference in number of thermocouples versus number of stages for a matched TEG in accordance with embodiments disclosed herein (solid line), compared to a matched TEG in accordance with the prior art approach (dashed line).

FIG. 30 shows the ratio of the thermal resistance of the thermopile due to conductivity through the thermopile legs to the serial resistance composed mainly of the thermal resistance of the heat source and the heat sink (solid line), and the ratio of the thermal resistance of the thermopile to the parallel parasitic thermal resistance of the air in between the cold and hot plates (dashed line) as a function of the number of thermocouples per stage. The matching point according to embodiments disclosed herein is marked with (▴). A prior art approach is marked with (∘).

FIG. 31 shows the ratio of the thermal resistance of the TEG to the serial resistance composed mainly of the thermal resistance of the heat source and the heat sink as a function of the number of thermocouples per stage. The matching point according to embodiments disclosed herein is marked with (▴). A prior art approach is marked with (∘).

FIG. 32 shows a TEG in accordance with embodiments disclosed herein, wherein thermopiles fabricated according to US 2006/0000502 are provided in a multi-stage arrangement (three stages are shown).

FIG. 33 shows the power for a different number of thermopile stages in embodiments using the micromachined thermopiles fabricated according to US 2006/0000502. The matching point according to such embodiments is marked with (▴). A prior art approach is marked with (∘).

FIG. 34 shows an increase of electrical power due to better thermal matching as proposed herein, as compared with a prior art approach.

FIG. 35 shows an increase of electrical power due to the multi-stage arrangement of the thermopile unit proposed herein as compared with a prior art approach.

FIG. 36 shows the sum of two effects separately manifesting themselves in FIGS. 34, 35 on power, illustrating the joint effect of better matching and the multi-stage arrangement of the thermopile unit as proposed herein.

FIG. 37 shows the electrical power produced by a TEG matched using a method described herein (solid line) compared to the power produced when using a prior art approach (dashed line), plotted versus the number of stages.

FIG. 38 shows the electrical power produced by a TEG matched using a method of embodiments described herein (solid line) compared to the power produced when using a prior art approach (dashed line) plotted versus number of thermocouples in the TEG.

FIG. 39 shows the ratio of the voltage of a TEG matched according to embodiments described herein to the voltage of the TEG matched using the prior art approach, as a function of the number of stages.

FIG. 40 shows a TEG with radiation shield (reflector) in accordance with embodiments described herein.

FIG. 41 shows a TEG incorporated into clothes, in accordance with embodiments described herein.

FIG. 42 shows a TEG fabricated as a “button” implemented into a garment, in accordance with embodiments described herein. A case where three garments are worn on top of each other is shown, with heat transferring buttons in the layers covering the inner one with a TEG in accordance with embodiments described herein.

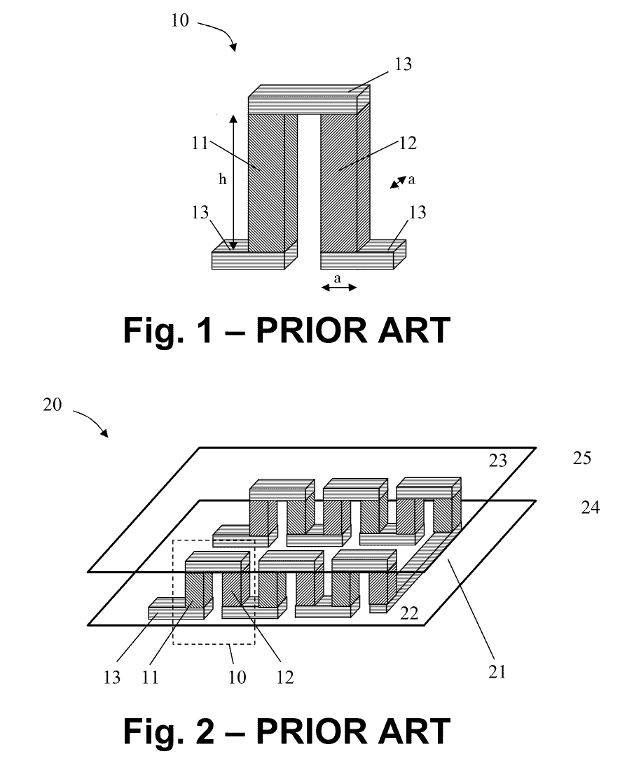

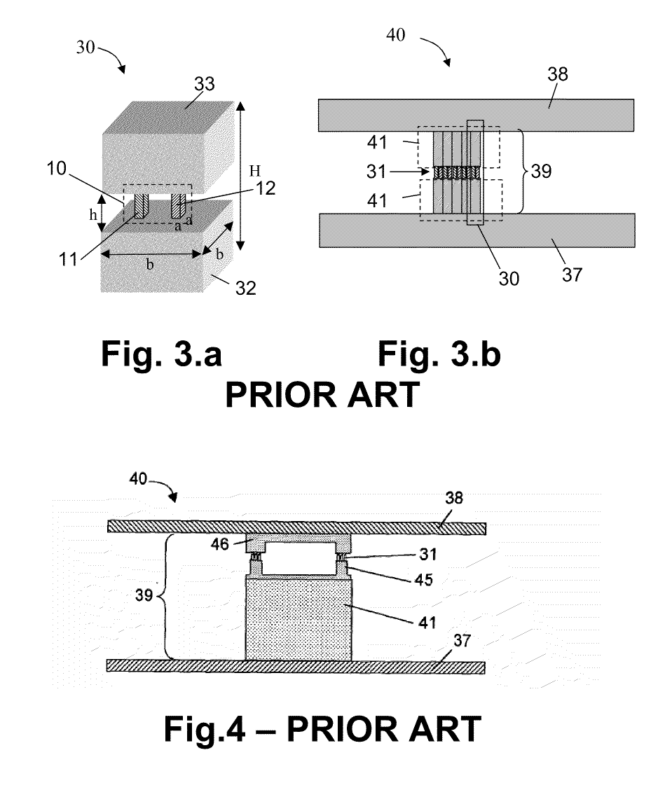

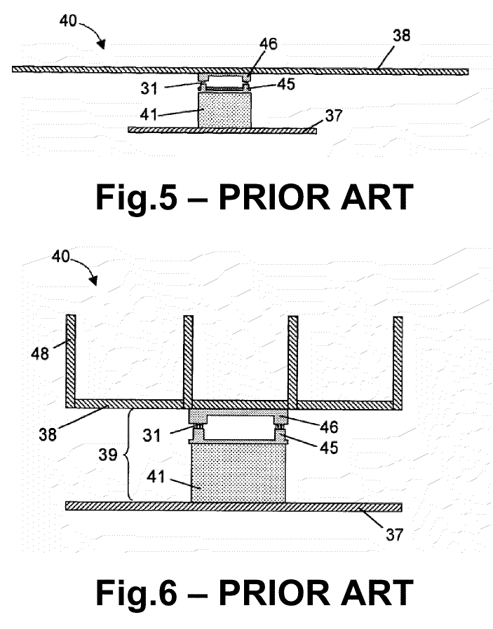

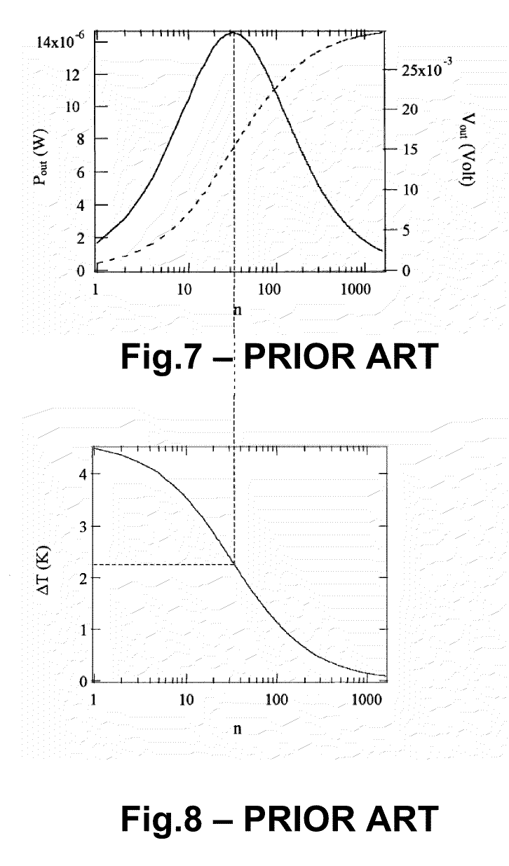

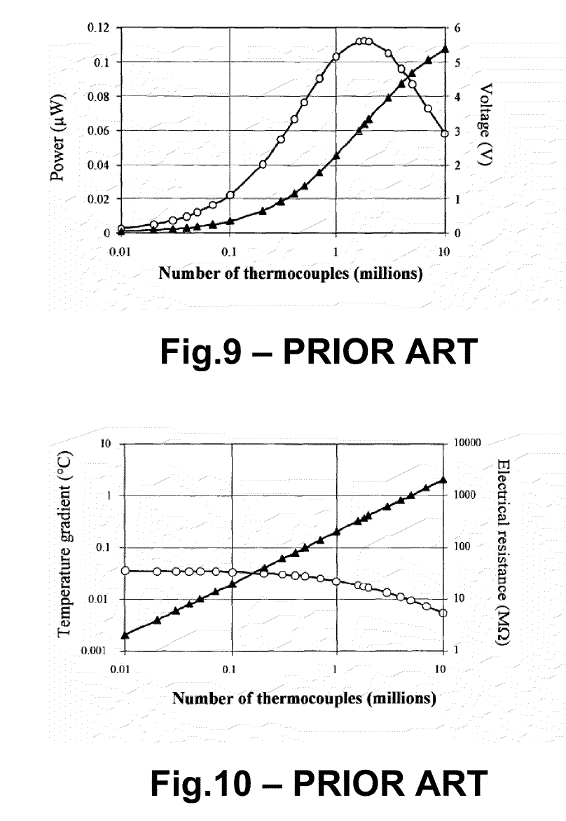

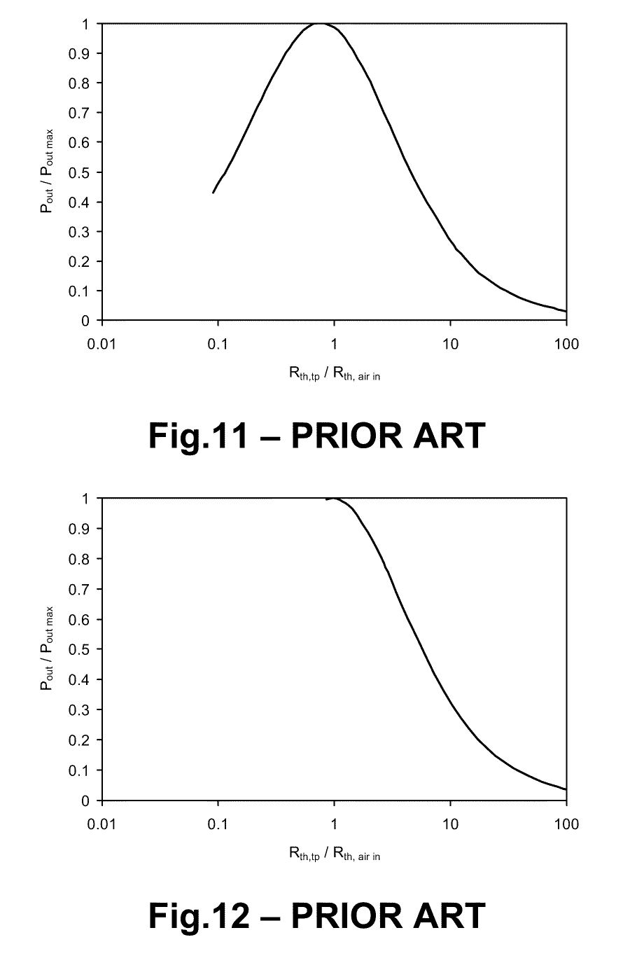

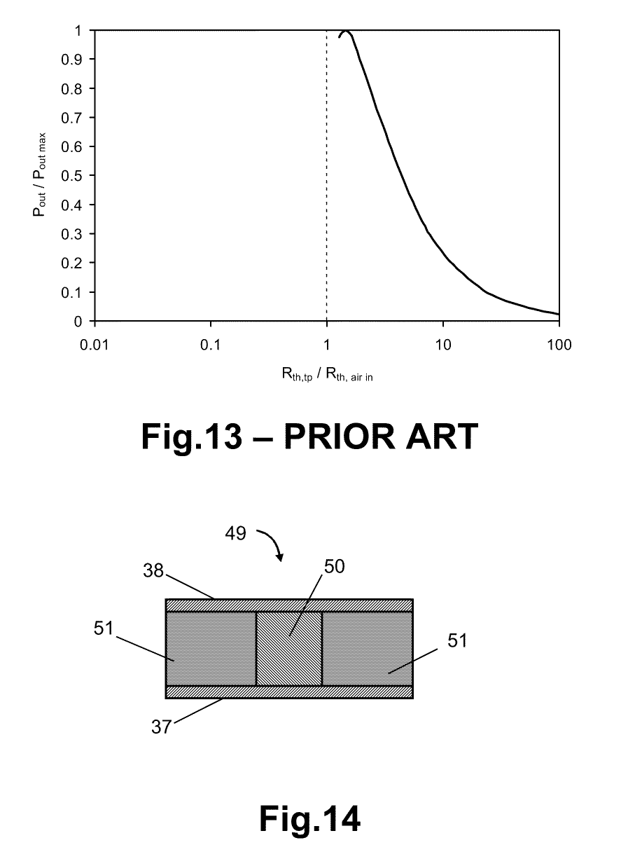

In the different figures, the same reference signs refer to the same or analogous elements.

### DETAILED DESCRIPTION

In the following detailed description, numerous specific details are set forth in order to provide a thorough understanding of the invention and how it may be practiced in particular embodiments. However it will be understood that the present invention may be practiced without these specific details. In other instances, well-known methods, procedures and techniques have not been described in detail, so as not to obscure the present invention. While the present invention will be described with respect to particular embodiments and with reference to certain drawings, the invention is not limited thereto. The drawings included and described herein are only schematic and are not limiting the scope of the invention. It is also noted that in the drawings, the size of some elements may be exaggerated and, therefore, not drawn to scale for illustrative purposes. The dimensions and the relative dimensions do not necessarily correspond to those of actual reductions to practice of the invention.

Furthermore, the terms first, second and the like in the description and in the claims, are used for distinguishing between similar elements and not necessarily for describing a sequence, either temporally, spatially, in ranking or in any other manner. It is to be understood that the terms so used are interchangeable under appropriate circumstances and that the embodiments of the invention described herein are capable of operation in other sequences than described or illustrated herein.

Moreover, the terms top, bottom, over, under and the like in the description and the claims are used for descriptive purposes and not necessarily for describing relative positions. It is to be understood that the terms so used are interchangeable under appropriate circumstances and that the embodiments of the invention described herein are capable of operation in other orientations than described or illustrated herein.

It is to be noticed that the term “comprising”, used in the claims, should not be interpreted as being restricted to the means listed thereafter; it does not exclude other elements or steps. It is thus to be interpreted as specifying the presence of the stated features, integers, steps or components as referred to, but does not preclude the presence or addition of one or more other features, integers, steps or components, or groups thereof. Thus, the scope of the expression “a device comprising means A and B” should not be limited to devices consisting only of components A and B.

A TEG 49 as illustrated in FIG. 14 comprises a thermopile unit 50, comprising at least one thermopile 21, which in its simplest shape is formed by a plurality of thermocouples 10 electrically connected in series, and placed in between plates 37, 38. The thermopile unit 50 may further comprise other elements which will be explained below. A thermal isolation 51 may be present at one or more sides of the thermopile unit 50, and may be formed by vacuum, air or another insulating material, and may include pillars and/or encapsulating structures.

When designing a TEG 49 for operation under conditions of non-constant heat flow and non-constant temperature difference, it is desirable to into account the characteristics of the environment and for matching the thermal resistance of the TEG 49 to the ambient. It can be shown that the temperature difference ΔT_{TEG,opt} between the hot junction plane and the cold junction plane of a thermoelectric generator corresponding to the maximal power output is given by:

$$Δ {T}_{T E G , opt} = \frac{Δ T}{2} \frac{{G}_{amb}}{{G}_{amb} + {G}_{T E G , 0}} \qquad ( 8 )$$

wherein ΔT is the temperature difference between the heat source and the heat sink, G_{amb} is the thermal conductance of the ambient (including the heat source and the heat sink and the parts of the thermoelectric generator serially coupled to the thermopile) and G_{TEG,0} is the thermal conductance of the same thermoelectric generator in the limit as the number of thermocouples approaches zero (that is, the hypothetical thermal conductance of the same thermoelectric generator, but with no thermocouples or with, for example, only one thermocouple leg).

In general, the thermal conductance of the ambient G_{amb} is a nonlinear function of the temperature because it includes air convection and thermal radiation terms. The thermal conductance of the ambient at maximum power conditions is further denoted as G_{amb,opt}, or 1/R_{amb,opt}.

The temperature drop on a TEG with no thermocouples or with one thermocouple leg is given by:

$$\begin{matrix}Δ {T}_{T E G , 0} = Δ T \frac{{G}_{amb , 0}}{{G}_{amb , 0} + {G}_{T E G , 0}} = Δ T \frac{{R}_{T E G , 0}}{{R}_{T E G , 0} + {R}_{amb , 0}} \\ At maximum power conditions , equation ( 8 ) can be written as \text{:} & ( 9 ) \\ Δ {T}_{T E G , opt} = \frac{Δ T}{2} \frac{{G}_{amb , opt}}{{G}_{amb , opt} + {G}_{T E G , 0}} = \frac{Δ T}{2} \frac{{R}_{T E G , 0}}{{R}_{T E G , 0} + {R}_{amb , opt}} & ( 10 )\end{matrix}$$

From equations (9) and (10), the temperature difference between the hot junction and the cold junction at maximum power output is given by:

$$Δ {T}_{T E G , opt} = \frac{Δ {T}_{T E G , 0}}{2} \frac{{R}_{amb , 0} + {R}_{T E G , 0}}{{R}_{amb , opt} + {R}_{T E G , 0}} \qquad ( 11 )$$

If the thermal resistance of the ambient is constant, i.e. R_{amb,0}=R_{amb,opt}, equation (11) simplifies to:

$$Δ {T}_{T E G , opt} = \frac{Δ {T}_{T E G , 0}}{2} \qquad ( 12 )$$

Independently of the temperature behaviour of the ambient thermal resistance, equation (12) also holds if R_{TEG,0}>>R_{amb,0} and R_{TEG,0}>>R_{amb,opt}. In the optimized device, these inequalities may hold, at least in weak form (R_{TEG,0}>R_{amb,0} and R_{TEG,0}>R_{amb,opt}). Furthermore, in typical situations of energy scavengers, the ambient resistance does not vary greatly with temperature. For these reasons, equation (12) instead of equation (11) can often be used as a condition for optimizing the device.

Considering that ΔT_{TEG,0}=R_{TEG,0}W_{TEG,0} and ΔT_{TEG,opt}=R_{TEG,opt}W_{TEG,opt}, wherein W_{TEG,0} is the heat flow through the TEG in case there are no thermocouples or only one thermocouple leg, and wherein W_{TEG,opt} is the heat flow through the TEG at maximum power, equation (12) can be rewritten as:

$${R}_{T E G , opt} {W}_{T E G , opt} = \frac{{R}_{T E G , 0} {W}_{T E G , 0}}{2} \qquad ( 13 )$$

Replacing ΔT_{TEG,opt} and ΔT_{TEG,0} in (11), eliminating the heat flows using:

$${W}_{T E G , 0} = \frac{Δ T}{{R}_{amb , 0} + {R}_{T E G , 0}}$$

$$and$$

$${W}_{T E G , opt} = \frac{Δ T}{{R}_{amb , opt} + {R}_{T E G , opt}} ,$$

and solving equation (11) for R_{TEG,opt} results in:

$${R}_{T E G , opt} = \frac{{R}_{amb , opt} {R}_{T E G , 0}}{2 {R}_{amb , opt} + {R}_{T E G , 0}} \qquad ( 14 )$$

This equation can be solved by iterations. In the beginning, the value of R_{amb,0} can be used instead of R_{amb,opt}. Upon obtaining the first approximation value of R_{TEG,opt} the values of W_{TEG,opt} and R_{amb,opt} can be calculated more accurately. Only a few iterations are usually sufficient for obtaining a good accuracy.

In case equation (12) holds, equation (14) can be written as:

$${T}_{T E G , opt} = \frac{{R}_{amb , opt} {R}_{T E G , 0}}{2 {R}_{amb , 0} + {R}_{T E G , 0}} \qquad ( 15 )$$

The condition for obtaining thermal matching in the case of limited heat flow, in accordance with embodiments described herein, is given by equation (14):

$${R}_{T E G} = \frac{{R}_{amb} {R}_{T E G , 0}}{2 {R}_{amb} + {R}_{T E G , 0}} \qquad ( 14 )$$

where R_{TEG} is the desired thermal resistance of the thermoelectric generator between the hot junction plane 24 and the cold junction plane 25 of the thermopile (in case of a multi-stage thermopile as described further, between the hot junction plane comprising the hottest junctions and the cold junction plane comprising the coldest junctions); R_{amb} is the thermal resistance of the heat source and the heat sink serial to the thermopile, additionally including the comparatively small thermal resistance of the parts of the thermoelectric generator serially coupled to the thermopile 21, which for a well-matched device can be neglected; R_{TEG,0} is the thermal resistance of the thermoelectric generator of exactly the same design, between the hot junction plane 24 and the cold junction plane 25, in which there are no thermocouples, or in which only one thermocouple leg is present.

If condition (12) is fulfilled, the condition for thermal matching according to embodiments disclosed herein can be written as:

$${R}_{T E G} = \frac{{R}_{amb} {R}_{T E G , 0}}{2 {R}_{amb , 0} + {R}_{T E G , 0}} \qquad ( 15 )$$

wherein R_{amb,0} is the thermal resistance of the heat source and the heat sink serially coupled to the thermopile additionally including the comparatively small thermal resistance of the parts of the thermoelectric generator serially coupled to the thermopile 21, under condition that there are no thermocouples, or that only one thermocouple leg is present.

Condition (12) corresponds to the condition that the temperature drop over the thermopile 21 between the hot junction plane 24 and the cold junction plane 25 is equal to half of the temperature drop obtainable in a same embodiment at equal other relevant conditions, but when there are no thermocouple legs in between plates 37, 38, or there is only 1 thermocouple leg 11 or 12. In the case of a multi-stage thermopile unit (as described below), the temperature difference over the thermopile 21 is to be understood as the temperature difference over the multi-stage arrangement, between the hot junction plane 24 comprising the hottest junctions (closest to the hot plate 37) and the cold junction plane 25 comprising the coldest junctions (closest to the cold plate 38 or radiator 48). It is to be noted that this condition (12) is neither the same as in case one gets over the thermopile half of the available temperature difference between the heat source and the heat sink, ΔT_{source-sink} nor the same as in case there is equality of the thermal resistance of the thermopile legs or thermopile unit 50 and the thermal resistance of the thermal isolation 51, which is targeted in prior art TEGs. The thermal matching conditions (14) and (15) are valid for a condition of limited heat flow. Under condition of limited heat flow, the thermal resistance of the TEG is of the same order of magnitude as the thermal resistance of the ambient. The heat flow is then significantly different between two cases: heat flow in a TEG with the number of thermocouple legs calculated in accordance with embodiments of the present invention and heat flow in a corresponding TEG with no or with only one thermocouple leg. If only a small difference (e.g. a few percent) in heat flow is observed between the two cases (e.g. between a prior art TEG and a corresponding TEG with no or with only one thermocouple leg), this means that the TEG is not suited for applications with limited heat flow as in embodiments described herein.

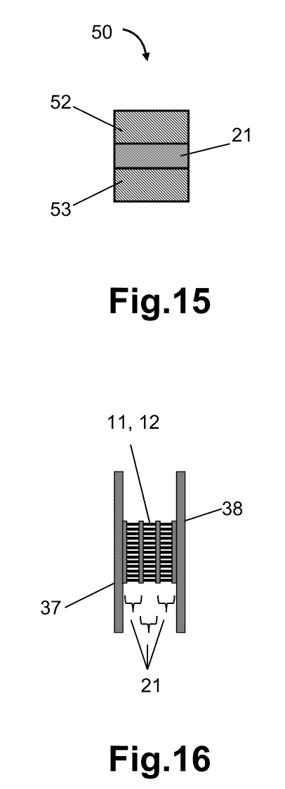

The performance of a TEG 49 as described above may be enhanced in several ways, e.g., (i) by adding at least one thermally conducting spacer 52, or 53, or two spacers 52, 53 into the thermopile unit 50, thus separating the thermopile 21, comprising a plurality of thermocouples coupled for example thermally in parallel and electrically in series, from at least one of the hot and/or the cold plates 37, 38, as illustrated in FIG. 15, and/or (ii) by varying the contact area of the TEG 49 with the heat source and the heat sink, i.e. changing the dimensions of the hot and/or cold plates 37, 38, and/or (iii) by appropriately choosing materials and design in order to obtain the desired thermal isolation between the hot plate 37 and the cold plate 38.

Hereinafter, these possibilities to enhance the performance of the TEG 49 according to embodiments described herein will be discussed for a TEG 49 attached to a wrist or to a forehead of a person. However, this is an example and is not intended to be limiting for the invention, which is applicable for all ambient heat sources and heat sinks with high thermal resistance (e.g. between 10 cm²K/W and 1000 cm² K/W), like, e.g. homeotherms, i.e. in case of limited heat flow.

At usual ambient temperatures, typically between 15 and 25° C., e.g. 20° C., the thermal resistance of the human body R_{th,body} ranges from about 100 cm² K/W to about 1000 cm²K/W with the possibility to be out of the mentioned range; the same holds for the thermal resistance of ambient air. Therefore, by increasing the contact area between the hot and cold plates 37, 38 and the ambient, i.e. by changing dimensions and/or shape of the hot and/or cold plates 37, 38, the heat flow from the body to the ambient can be enhanced. Increasing the contact area between the cold plate 38 and air may be done by, e.g., adding a radiator 48 to the cold plate 38 or by shaping the cold plate as a radiator 48 with developed surface like fins or pins (i.e. changing the shape and/or dimensions of the cold plate 38). The different shapes of the plates 37, 38, and of the radiator 48 also may offer significant improvement of the generated power. As an example, the human wrist has non-uniform temperature on its circumference, and a hot plate of 2×2 cm² placed on a radial or ulnar artery according to US 2006/0000502, provides better heat flow than prior art devices placed on the outer side of the wrist. However, reshaping this area into 1×4 cm² and placing it aligned with the artery produces a better heat flow on the same area, or better heat flow per square centimetre of the skin, resulting in better generated power.

The performance of the TEG 49, according to other embodiments, may be improved thus generating more power at equal ambient conditions (e.g. same air temperature, air speed, absorbed radiation, thermal resistance of heat source and heat sink), if at least one spacer 52, 53 is used, irrespective of any particular type of thermopiles used, e.g. commercial thermopiles, on a polymer tape, micromachined thermopiles, or thick/thin thermopiles on a membrane. Unlike the spacers in micromachined thermopiles fabricated according to US 2006/0000502, the height of which is at least 10 times larger than the height of thermopile 21, the proposed spacer 52, 53 is used to move the cold plate 38 or the radiator 48 out of the air jet of free convection occurring around the heat source, e.g. human body. The conditions when the thickness of the buoyancy-driven free boundary layer is thin enough to obtain a significant percentage of temperature drop at a distance from the hot plate (37) corresponding to the location of the cold plate (38) or the radiator (48) can be found. As an example, the temperature rise in the air around a horizontally positioned wrist decreases to 20% of the temperature difference between the air and the skin at about 7 mm from the skin.

Therefore, by introducing at least one spacer 52, 53 to make the distance in between the hot and cold plates 37, 38 equal to or more than 7 mm, the cold plate 38 is moved into the cold air. This causes decoupling of the Rayleigh number of the heat transfer at the surface of the cold plate (38) or at the surface of the radiator (48) from the one on a wrist and results in an increase of the heat transfer as compared with the TEG 49 without the at least one spacer 52, 53. The same effect is observed for the forced convection, when the Reynolds number of the heat transfer at the surface of the cold plate (38) or at the surface of the radiator (48) is improved. The desired spacer thickness may be smaller in this case because the boundary layer is thinner in case of forced convection. As an example, a standing animal is at free convection conditions, while a walking animal is at forced convection conditions.

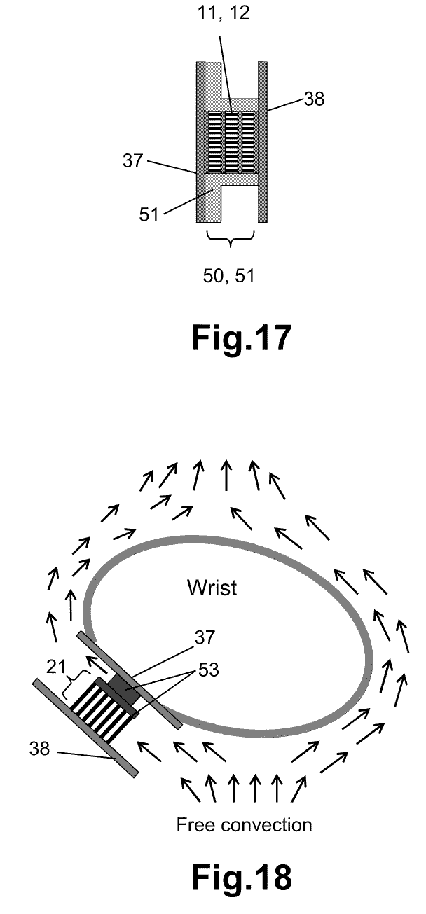

The spacer 52, 53 as discussed above is not necessary if the thermopile 21 is made with corresponding increase of its thickness, the thickness being defined as the average distance in between the hot junction plane 24 and the cold junction plane 25 in the direction of average heat flow, without deterioration of its properties. Therefore, if commercially available thermopiles are used to build the thermopile unit 50, these are preferably arranged into a multi-stage structure like the one shown in FIGS. 16, 17 so that the thermoelectric generator obeys the matching conditions (14) or (15). In FIG. 16, a three-stage thermoelectric generator 49 is shown, comprising three stacked thermopiles 21 or three thermopile stages. Stacking of thermopiles 21 results in an increased thickness of the thermoelectric generator 49, thus moving the cold plate 38 or the radiator 48 out of the air jet of free or forced convection around the heat source, and improving the Rayleigh or Reynolds number of the heat transfer at the surface of the cold plate 38 or at the surface of the radiator 48, resulting in an increase in power output. FIG. 17 shows a three-stage thermoelectric generator 49 with thermal isolation 51 (e.g. a nano-porous material), for decreasing the parasitic heat transfer from the hot plate 37 and the thermopile unit 50 to the air.

Similar to the one-stage thermoelectric generator, a multi-stage thermoelectric generator may further contain at least one spacer 52, 53 to further improve the Rayleigh/Reynolds number of the heat transfer at the surface of the cold plate 38 or at the surface of the radiator 48, thereby increasing the power production on cost of increased thickness of the TEG, FIG. 18, 19.

In case commercially available thermopiles or other non-micromachined thermopiles are used in a TEG 49 in accordance with embodiments disclosed herein, the minimal voltage requirement may dominate over the desire to obtain maximal power. The overall outer TEG size and its total thickness are also frequently limiting boundary conditions for practical applications of TEGs. In all these cases, thermal mismatching of the TEG, i.e. a certain deviation from the optimal power, is acceptable to make the TEG output voltage acceptable for the accompanying electronics. The output power is a weak function of the number of thermocouples near the maximum output power, which corresponds to the condition of thermal matching as given in (14) or (15).

The fact that the dependence of power on obeying the condition of thermal matching (14) or (15) is a weak function of the number of thermocouples near the maximum is a property of all matching curves. Therefore, some mismatch still allows obtaining better power output conditions in the case of limited heat flow as compared with corresponding prior art TEGs (i.e. TEGs wherein the number of thermocouples is calculated according to another matching condition, such as the prior art matching condition wherein the temperature difference over the thermopile unit 50 is equal to half of the temperature difference between the heat source and the heat sink). Consequently, some departure from an exact thermal match is contemplated within the scope of the present disclosure.

To understand the range of the mismatch within which the TEGs disclosed herein outperform prior art TEGs, the heat flow obtainable in a prior art TEG and of an exemplary TEG disclosed herein are evaluated and compared. The micromachined thermopiles as described by Infineon (M. Strasser, R. Aigner, C. Lauterbach, T. F. Sturm, M. Franosch and G. Wachutka in “Micromachined CMOS Thermoelectric Generators as On-chip Power Supply”, Transducers '03. 12th International Conference on Solid State Sensors, Actuators and Microsystems, p. 45-48, 2003) do not show a change in the heat flow through the TEG if the 1 cm² area of the plates is completely filled with thermocouples as compared to the same device with only one thermocouple leg or no thermocouples. The modelling of the micromachined device used for calculation of FIG. 12, gives less than 1% variation of the heat flow. For the best-suited thermopiles for human body applications fabricated in the past at Seiko (M. Kishi, H. Nemoto, T. Hamao, M. Yamamoto, S. Sudou, M. Mandai and S. Yamamoto in “Micro-Thermoelectric Modules and Their Application to Wristwatches as an Energy Source”, Proceedings ICT'99 18^{th} Int. Conference on Thermoelectrics (1999), p. 301-307), at 1 cm² area of the plates, 22° C. ambient temperature and R_{th,body} of 440 cm² K/W which is observed on the human body where the watch comprising the TEG is worn, calculations show that the decrease of the heat flow if there would be no thermocouples, reaches only about 4%. Contrary thereto, the matching conditions of embodiments disclosed herein provide as a side effect a variation of the heat flow through an optimized thermopile unit by at least several tens of percent as compared to the same thermopile design with only 1 thermocouple leg or no thermocouples (a numerical example is calculated below). Moreover, the possibility of mismatching (which has an adverse effect on the TEG power) is usually considered only if the voltage is not high enough for effectively using the generated power, so that there is a need for increasing the corresponding number of thermocouples and the related heat flow to obtain the required output voltage. Therefore, it may be concluded that mismatched TEGs as described herein may outperform prior art TEGs if the heat flow increases by e.g. more than 5% in the TEG as compared with the same TEG with no thermocouples in it or with only 1 thermocouple leg remaining. The thermal matching curve according to the prior art is shown in FIG. 20 for the above example (Seiko). As one can see, a small but distinct misalignment between the R_{th,tp}/R_{th, air in} corresponding to the maximum in the output power and the unity of R_{th,tp}/R_{th, air in} is observed. For the case of thermal matching conditions in accordance with embodiments described herein, FIG. 20 is re-plotted in FIG. 21 versus ΔT_{TEG}/ΔT_{TEG,0} (solid line) together with the change of the heat flow (dashed line). The maximal power is reached at ΔT_{TEG}/ΔT_{TEG,0}=0.5 (corresponding to equation (12)). The mismatching means making ΔT_{TEG}/ΔT_{TEG,0}<0.5 or ΔT_{TEG}/ΔT_{TEG,0}>0.5.

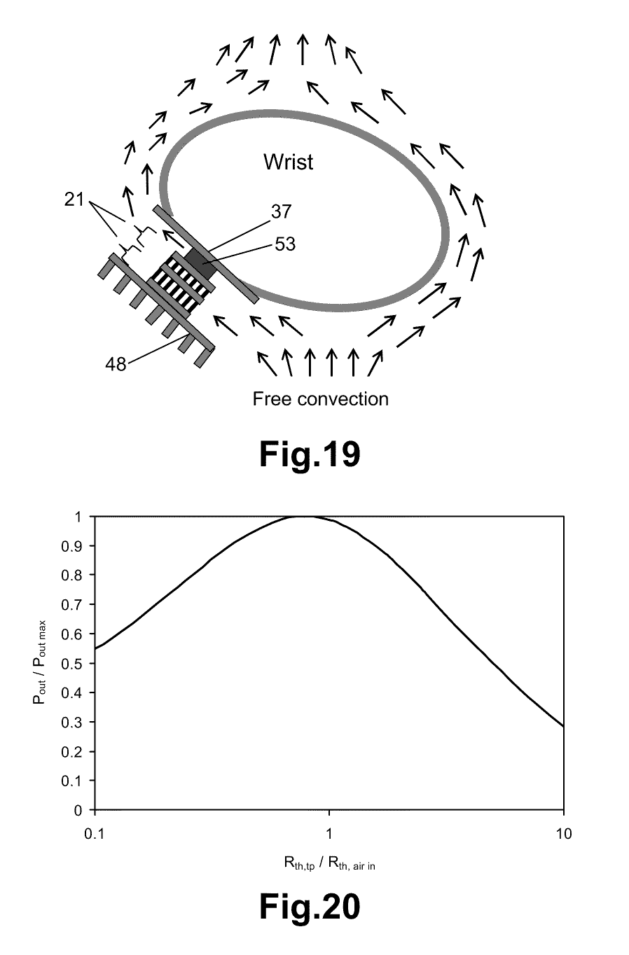

In examples of TEGs that obey the thermal matching conditions described herein, as shown in FIGS. 16 to 19, any suitable thermopile types may be used, e.g. thermopiles on polymer substrate, micromachined thermopiles or membrane-type thermopiles.

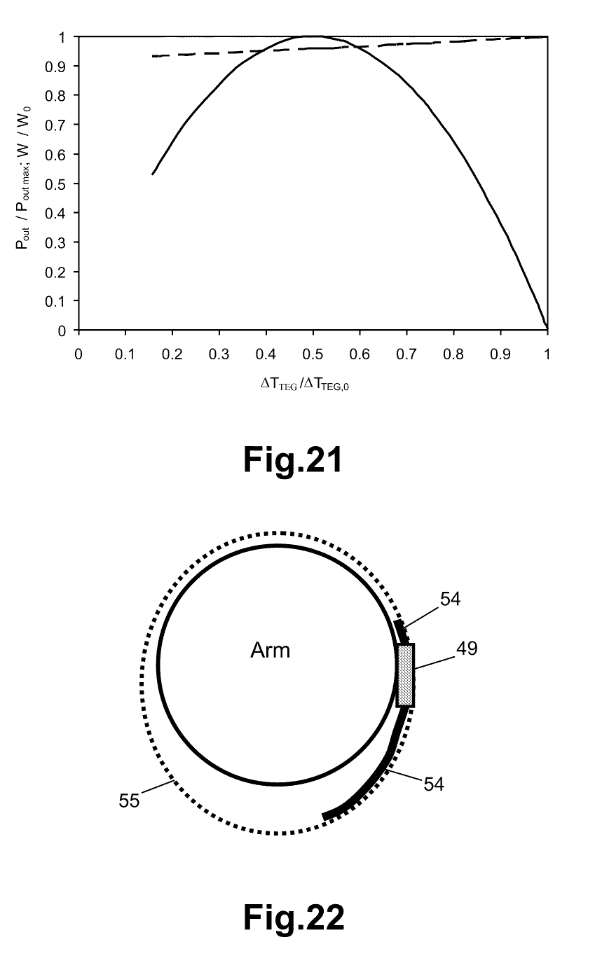

One or more effective rigid or flexible thermal isolation sheets 54 may furthermore be introduced to a garment 55 of homeotherms, e.g. human beings, as depicted in FIG. 22 as an example only, where the example on an arm is shown, while the garment 55 is shown as a dotted line. The thermal isolation sheets 54 thermally isolate the cold plate of the TEG 49 from the heat source and from the air jet of free or forced convection. The garment 55 itself can also serve as a thermal barrier. Such garment or isolation sheets may create larger thermal gradient per centimetre distance from the skin than occurs in the convective boundary layer. In this case, the total thickness of the TEG 49 required for reaching the low-temperature region of the boundary layer may decrease and the overall thickness of the TEG 49, including the thickness of spacers in a direction of the heat flow, approximately normal to the skin surface, may be reduced while still obeying the matching conditions described herein. Proper positioning of the TEG 49 in the areas on a body of a homeotherm where the boundary layer has the lower thickness may also help to decrease the required thickness of the TEG 49.

Positioning the TEG 49 on areas of the body of a homeotherm proximal to the body inner organs referred to as a core of the body, e.g. the brain, may allow further increase of the generated power as has been found in experiments. In case of a human being, the optimal position of the TEG 49 is on the temples of the head and on the forehead. In this case, the TEG 49 becomes effective also during nocturnal time on a sleeping person. For a sleeping person, however, in case of a TEG 49 on a temple, both temples preferably may be provided with TEGs 49 in case one of them is positioned on the pillow and thus producing lower power.

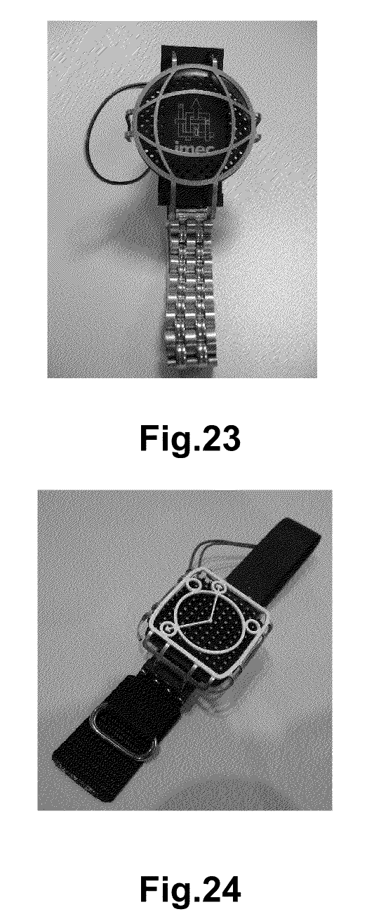

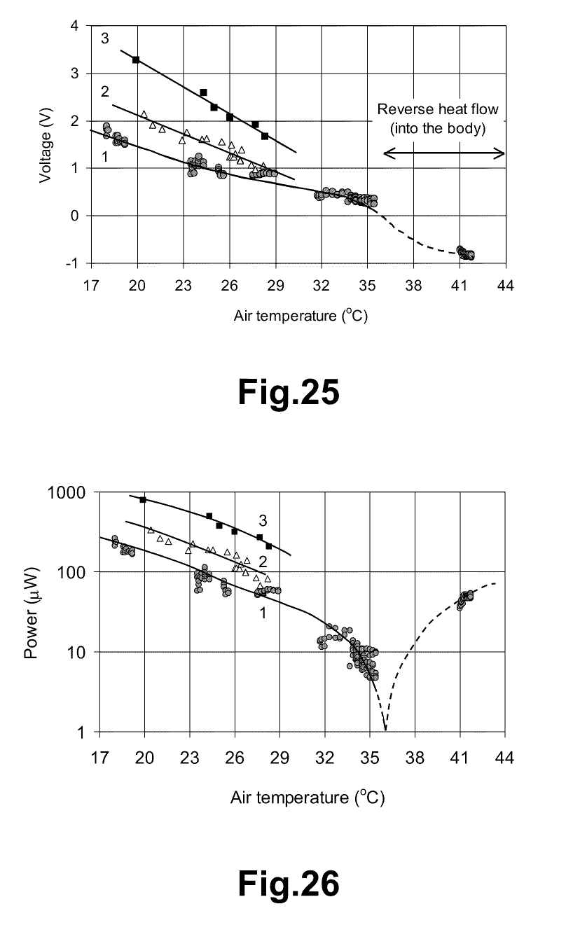

In FIGS. 23, 24 photos of practical devices using TEGs disclosed herein are shown. The measured performance of these devices is reported in FIGS. 25, 26, showing the open circuit voltage and the power as a function of air temperature. For both FIG. 25 and FIG. 26, curve (1) refers to measurements on a person quietly sitting for a very long time (hours) with no intermediate activity; curve (2) is obtained when a person performs usual office activity (walking in between offices, working on PC, etc.) in between the measurements, however, at least 5-10 minutes before the measurements, all activity is interrupted, and (3) is measured on a person walking indoor at about 4 km/hr.

In order to quantify the effect of embodiments disclosed herein, examples of calculations have been performed for three types of thermopiles: for a commercially available thermopile and for two different micromachined thermopiles.

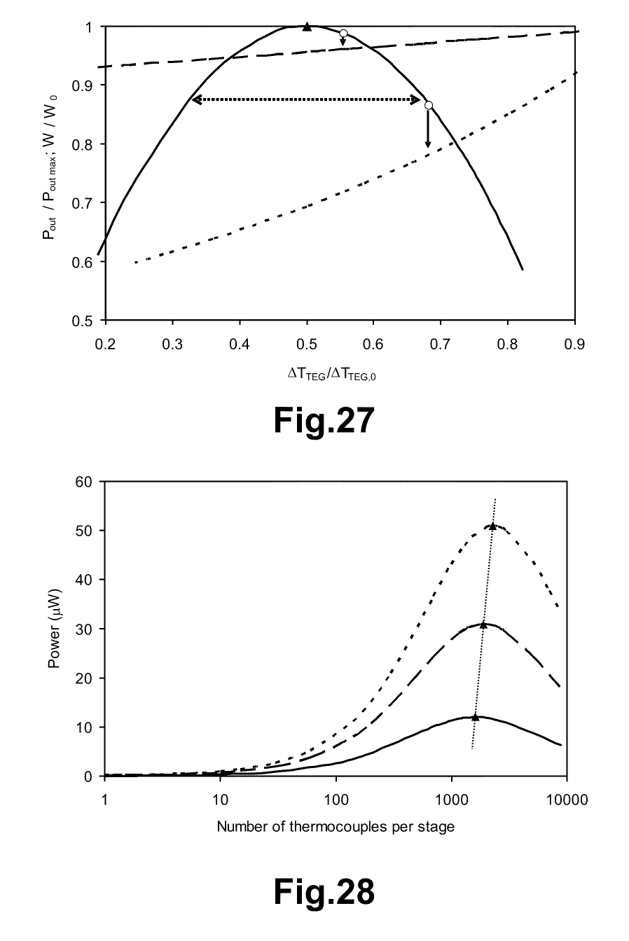

The calculation of the commercially available thermopile is performed using an example of a bismuth telluride (BiTe) thermopile of a Seiko watch. It is assumed that the thermocouple legs are 0.6 mm long, their lateral size is 0.8 mm, and the area occupied by one leg cannot be less than 0.2×0.2 mm², which can be considered as the state of the art in industrial technologies. The thermal resistance of the body is 440 cm²K/W at the location of the watch; the air temperature is 22° C. It is assumed that the radiating area of the watch body is 7 cm² and the contact area of the watch with the wrist is a circle of 2 cm² in diameter. Ten thermopile chips of 2×2 mm² each are used in the watch. In such arrangement, the thermopile is not well suited for application on a human body, because the thermal resistance of the thermopile is mismatched to both the thermal resistance of the ambient air and to the thermal resistance of the body. The matching condition according to the state of the art approach cannot be reached, therefore a larger area of the chip is assumed, 1×1 cm², which is to replace ten smaller units used in the watch. At this condition, the equality of the heat flow through the thermopile and through the air, as in the prior art matching condition, is reached at 1300 thermocouples on the chip, affording 11.8 μW power. The heat flow from the body changes by only 4% as compared with the case with no thermocouples in the TEG, or with only one thermocouple leg in it. If the conditions of matching described herein are applied, 1620 thermocouples would be used. However, the TEG does not work efficiently and the heat flow from the body changes by only 4.5%. The matching curve as needed for the prior art matching condition, plotted against the ratio R_{th,tp}/R_{th, air in}, is shown in FIG. 20, while for the matching condition in accordance with embodiments disclosed herein, the power is plotted in FIG. 21 versus ΔT_{TEG}/ΔT_{TEG,0} (solid line). The difference between the two matching conditions becomes clear from FIG. 27, where the results of a ten-stage thermopile and the results for a one-stage thermopile are both plotted. The matching curves (solid line) for one stage and ten stages coincide with each other if expressed in function of ΔT_{TEG}/ΔT_{TEG,0}. The heat flow through the TEG is shown as a dashed line for the one-stage thermopile and as a dotted line for the ten-stage thermopile. In the latter case one can see a large decrease of the heat flow W_{TEG} as compared with the case with no thermocouples or with 1 thermocouple leg W_{TEG,0}. The matching point (at the maximal power) is at the same place (▴) for the matching described herein, while for the prior art matching it moves from the upper point to a lower one, marked with (∘) for both the case of a one-stage and a ten-stage thermopile, with vertical arrows pointing at the corresponding heat flow. These prior art matching points do not reflect the true power optimum. As has been mentioned above, the thermopile under consideration is not well suited for a human body, as can be seen from the dashed heat flow curve, which does not show a large decrease near the matching point. A multi-stage arrangement, to the contrary, gives a large and advantageous decrease of the heat flow, as can be seen from the dotted line. In the case of one- and ten-stage thermopiles, the number of thermocouples corresponding to the matching condition (▴) described herein offers higher power compared to the prior art matching.

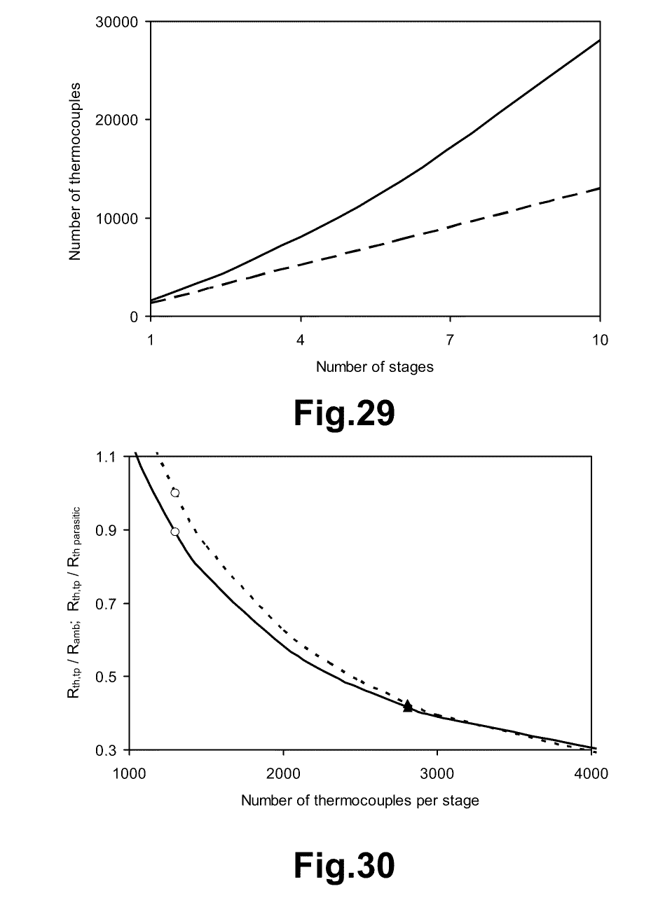

The dependence of absolute power on the number of thermocouples per stage, calculated for the case of one-stage, three-stage and six-stage thermopiles is shown in FIG. 28 as solid, dashed and dotted curves, respectively. The dotted straight line shows that the point when matching is reached shifts in the direction of increasing number of thermocouples per stage for an increased number of stages. At six stages, the power increases more than five times as compared to a one-stage TEG. The number of thermocouples required to reach the power maximum, calculated based on the matching conditions described herein (FIG. 29, solid line) exceeds by about a coefficient of 2 the number of thermocouples obtained based on the prior art matching condition R_{th,tp}=R_{th, air in} on several-stage thermopiles (FIG. 29, dashed line). The different number of required thermocouples for a same number of stages reflects different matching conditions.

FIG. 27 also suggests a useful range for a mismatch from exact compliance with the matching conditions described herein. One such range is marked in FIG. 27 with a horizontal arrow for a ten-stage thermopile. In this range, the generated power exceeds the one marked with (∘) which corresponds to the prior art matching condition.

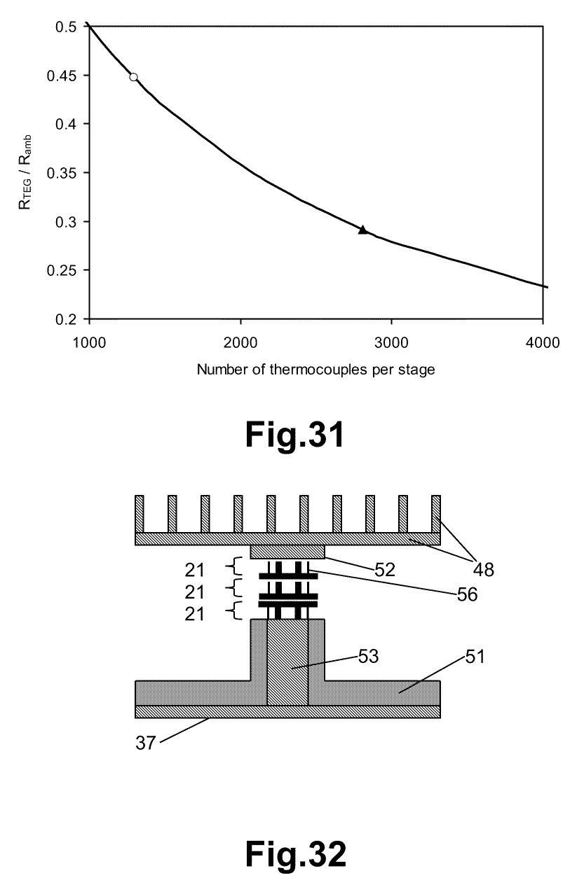

FIG. 30 shows the ratio of the thermal resistance of the thermopile due to conductivity through the thermopile legs to the serial resistance composed mainly of the thermal resistance of the heat source and the heat sink (R_{th,tp}/R_{amb}-solid line), and the ratio of the thermal resistance of the thermopile to the parallel parasitic thermal resistance of the air in between the cold and hot plates (R_{th,tp}/R_{th parasitic}-dashed line). FIG. 31 shows the ratio of the thermal resistance of the TEG to the serial resistance composed mainly of the thermal resistance of the heat source and the heat sink (R_{TEG}/R_{amb}). In FIGS. 30, 31 the ratios are shown for a ten-stage thermopile with the optimal points in accordance with embodiments described herein (▴) and according to the prior art (∘). It can easily be seen that the different matching conditions lead to quite different results, more particularly to quite different numbers of thermocouples per stage.

The present disclosure, in particular the matching condition to be applied for calculation of the number of thermocouples in the thermopile or thermopile stage, is especially useful for “difficult” sources of heat for energy scavenging, e.g. those with very low thermal gradients and very high thermal resistance. Therefore, the case of the commercially available thermopile calculated above does not show all advantages of the methods and devices disclosed herein. Micromachined thermopiles could be better suited for such applications. More particularly, thermopiles as in US 2006/0000502 but with a number of thermocouples calculated as described herein can provide a good thermal matching to such kind of heat source.

A micromachined thermopile on a raised elongate structure 53 made according to US 2006/0000502, which is referred to herein as a spacer, is now considered. One of the possible arrangements for a three-stage TEG is shown in FIG. 32, where the thermopile stages 21 are shown separated from each other for better understanding of the design. Two cases will be discussed: a thermopile well-optimised in accordance with embodiments described herein and a lower quality thermopile that is not so optimised, e.g. it is optimized in accordance with the prior art. Then the effects or results will be compared. Differences between the different effects of the matching and the multi-stage arrangement of a TEG will be made clear.

As an example, a well-optimised thermopile made of bismuth telluride according to US 2006/0000502 is supposed to be placed on an artery with a body thermal resistance of 200 cm²K/W. The thermocouples are 5 μm tall with a lateral size of 1 μm. One thermocouple occupies 10×10 μm² area of the die on top of the spacer 53. The thermopile stages 21 of 1×1 cm² size are assumed to have a thickness of 1 mm and the material properties are as in Table I. Different numbers of thermopile stages 21 are placed in between the hot plate 37 of 3×3 cm² size and the radiator 48 with fins or pins having 3×3 cm² size and an effective contact area to the air of 18 cm² due to fins or pins. The radiator 48 is placed at 1 cm² distance from the hot plate 37 where the Rayleigh/Reynolds numbers of the heat transfer at the surface of the cold plate 38 or at the surface of the radiator 48 are increased due to decoupling them from the ones on the skin. As in the previous example, the ambient air temperature is 22° C. In order to thermally connect the hot plate 37, thermopile chips 21 and the radiator 48, spacers 52, 53 may be used if the number of stages is less than 10. In order to hold the radiator 48 and the stages 21 on top of the thermopiles without damaging them, each thermopile stage 21 has a number of, e.g. four, silicon pillars 56 of 10×10 μm² lateral size with 7440 K/W thermal resistance parallel to the thermopiles, i.e. a parasitic thermal resistance.

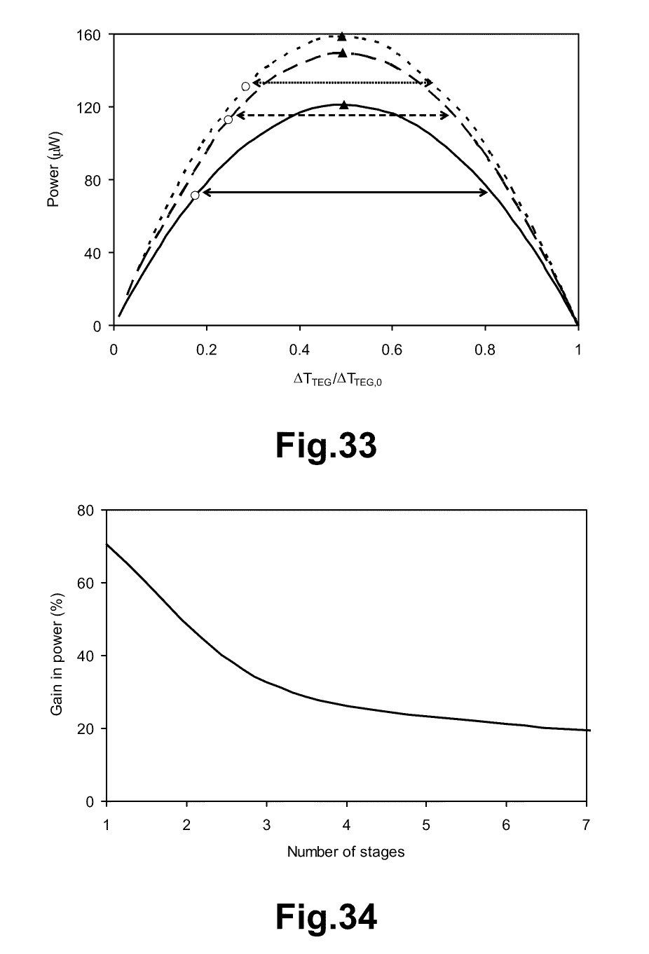

FIG. 33, solid line, shows the results of the modelling of a one-stage thermoelectric generator according to US 2006/0000502. The circle, as before, shows the result of matching according to the prior art, and the triangle shows the result of matching in accordance with embodiments described herein, which is better with respect to power output, as can be appreciated from the graph of FIG. 33. The effect of a multi-stage arrangement is shown for a three-stage and a six-stage thermopile, by the dashed and dotted curves, respectively. The horizontal arrows, as in FIG. 27, show ranges where the matching in accordance with embodiments described herein has an advantage over the prior art in case a larger or lesser voltage than at the matching point (▴) is desirable. The multi-stage arrangement also offers better performance as compared to the one-stage thermoelectric generator according to US 2006/0000502 because the maximal power increases from about 120 μW to about 160 μW at the same size of the TEG.

FIG. 34 shows the gain in power due to the better matching, as a function of the number of thermopile stages, as compared with prior art matching. It is shown that for a one-stage thermoelectric generator for which the number of thermocouples is calculated in accordance with the matching condition (15), the output power is about 70% higher than for a one-stage thermoelectric generator with the number of thermocouples calculated according to prior art matching. The gain in power decreases for an increasing number of stages, and amounts to about 20% for a seven-stage generator.

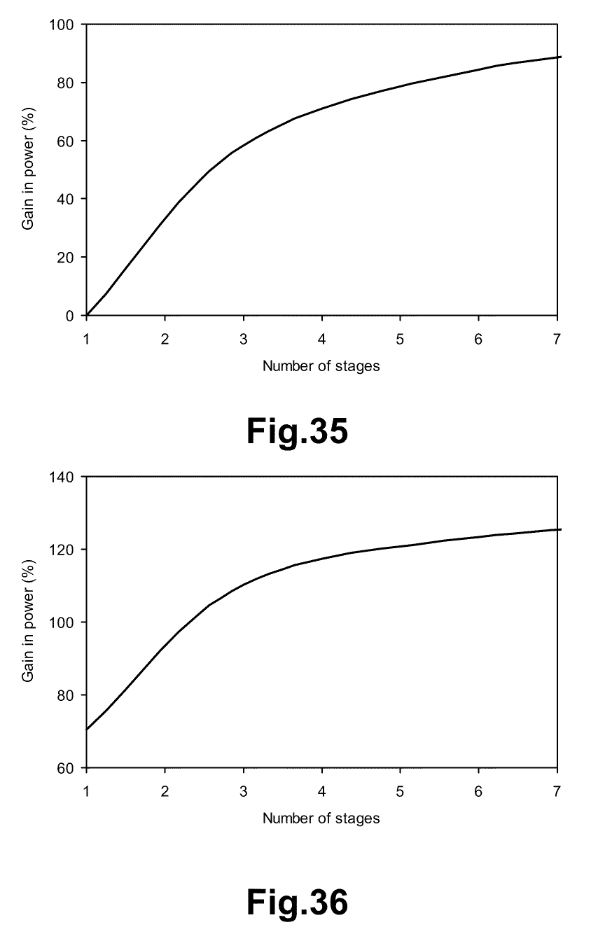

FIG. 35 shows the gain in power for a multi-stage design, as compared with a one-stage thermoelectric generator according to US 2006/0000502, wherein the number of thermocouples is calculated according to prior art matching. FIG. 35 shows the effect of a multi-stage arrangement for prior-art thermoelectric generators. For the case considered here, the power generated by a two-stage thermoelectric generator is more than 30% higher than for a one-stage generator. For a seven-stage generator, the gain in power is about 90% as compared to a one-stage generator.

FIG. 36 is a sum of both effects shown in FIGS. 34 and 35, showing that the effects are independent, and summation with each other gives about 70% rise in power with a one-stage thermoelectric generator thermally matched as described herein and more than 2.2 times improvement in power for a seven-stage thermoelectric generator thermally matched as described herein, as compared with a one-stage embodiment that is thermally matched according to the prior art.

When considering a further, third example of the matching and multi-stage arrangement, a similar TEG as above, but less optimal, will be discussed. The device thickness is assumed to be 12 mm; the hot and cold plates are similar to each other in size and shape, and have a size of 3×3 cm² each and 1 mm thickness. Different numbers of thermopile stages as discussed in US 2006/0000502 are used; the stages are 1 mm thick, as in the previous example. It is now assumed that thermocouple legs are 3 μm long with a lateral size of 1 μm; one thermocouple leg occupies an area of 20×20 μm² on the chip surface. Thermocouples are made of polycrystalline silicon germanium with a thermal conductivity of 0.03 W/cm.K, an electrical resistivity of 2 mΩ.cm and a Seebeck coefficient of 0.1 mV/K. The shock protection and mechanical stiffness of the TEG is provided with a polymer wall of 1 mm thick on the perimeter of the device connecting the hot and cold plates and encapsulating its inner volume, but making a parasitic thermal conductance of 658 K/W.

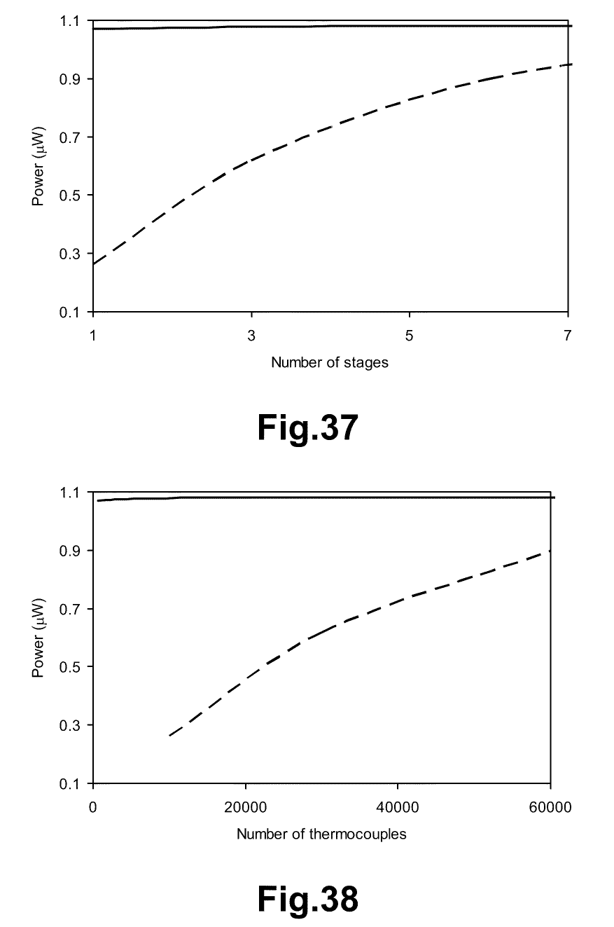

In the design under consideration, the parasitic thermal conductance through the air on top of the on-chip spacer exceeds the useful conductance through the thermopile, so it is actually not a well-suited device for the chosen application. Therefore, the increased number of stages does not offer the corresponding rise of the power, as illustrated in FIG. 37, solid line. The dashed line, however, which shows the matching in accordance with the prior art, lies well below the solid line, once more confirming the advantageous effect of thermal matching as described herein. Thermal matching as described herein also has an advantageous effect as compared to prior art matching, for a given number of thermocouples. This is depicted in FIG. 38, where the solid line is for the matching described here and the dashed line is for the prior art. It is clear from FIGS. 37, 38 that if a larger voltage is required than the one obtained at the optimal point, a thermal mismatch (as compared with an exact match described herein) can be performed because, e.g., at one stage, a four-fold improvement in generated power is obtained, compared to the prior art situation.

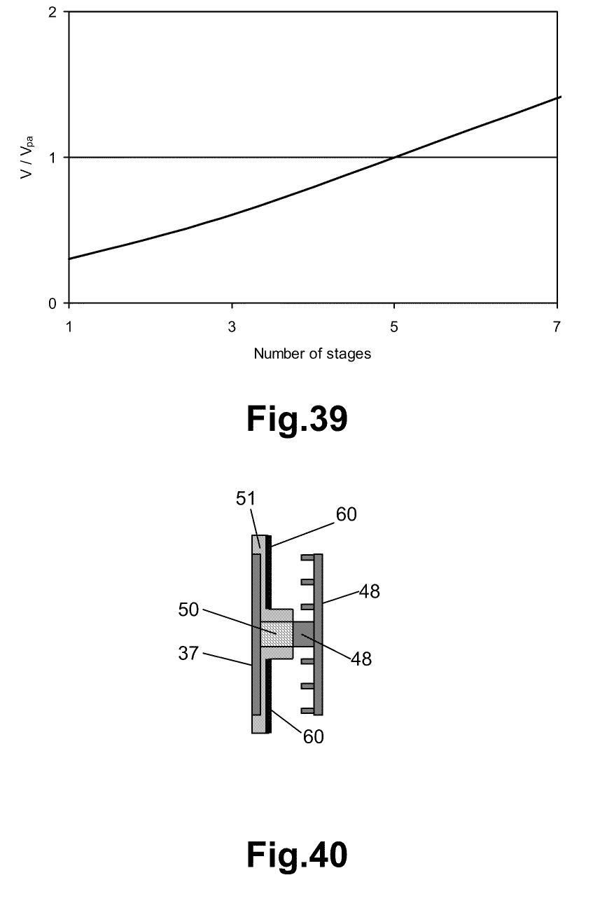

FIG. 39, in addition, shows one more advantage of the matching in accordance with embodiments described herein for the case under consideration. When the number of stages exceeds five, the voltage also exceeds the prior art level Vₚₐ together with the power. It increases to about 140% as compared to the prior art at seven stages, and it further increases up to two-fold improvement as compared to the prior art at ten stages (extrapolation).

To prevent or suppress the radiation heat exchange inside the TEG 49, one or more, and preferably all, inner surfaces of the TEG 49 may have low emissivity (lower than 20%, preferably lower than 10%) in the infrared region of the electromagnetic spectrum. For example, a number of metals may serve as low-emissivity materials. Thus, if plastics or other materials used for forming the TEG 49 have high emissivity, they preferably are covered with highly reflecting (low emissivity) material, such as for example a metal. The inner surfaces of the TEG are the surfaces of the structures comprised in the TEG, in between the hot plate 37 and the cold plate 38 or the radiator 48.

For better thermal isolation of the cold plate 38 or/and radiator 48 from the warmer parts of the TEG 49 and a heat source, the inner volume of the TEG 49 as well as the volume on or in between the thermopile stages 21 (or in between chips 45, 46, if heat-spreading chips 46 are used) can be filled with a material showing lower thermal conductivity than the ambient, for example air, e.g. a microporous or nanoporous material. This is especially related to the TEGs in accordance with embodiments described herein, which are incorporated into a garment, when their thickness may be reduced as compared with a TEG on open skin surface.

In order to increase radiant heat exchange from an inner surface of the radiator 48 or from the cold plate 38 into the ambient, the inner surface of the radiator or of the cold plate preferably has a high emissivity (higher than 90%, preferably higher than 95%) in the wavelength range of thermal radiation (e.g. between 7 μm and 14 μm). Then, the inner surface of the hot plate 37 may have a low emissivity (lower than 20%, preferably lower than 10%) in the infrared region. In some embodiments, a TEG 49 is provided with a shield or screen 60 with a low emissivity in the infrared region. The screen 60 may be installed in between and thermally isolated, for example by means of thermal isolation 51, from the hot plate 37 and the cold plate 38 or radiator 48. This is illustrated in FIG. 40.

As a TEG 49 may also be used for outdoor applications at temperatures above body core temperature and with a radiant heat from sun or from ambient (e.g. in a desert when the sand is heated to e.g. about 40-90° C.), the TEG 49 may be used in reverse mode of operation, e.g. when the heat flow direction is from the ambient into a body, or to another surface, on which the device is mounted. For this type of applications, the outer surface of the cold plate 38 or radiator 48 may have a low absorption in the visible and near-infrared spectral regions, but may still have a high emissivity in the far-infrared, where the radiator emits thermal radiation. The measured voltage generation on a practical device in reverse mode is illustrated in FIG. 25 at temperatures of 41-42° C.; the correspondingly generated power can be seen in FIG. 26.

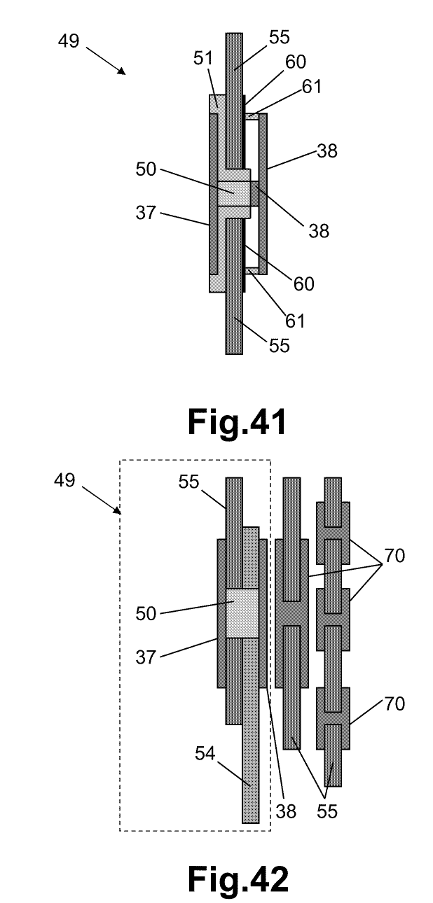

FIG. 41 shows a cross-section of a possible implementation of a TEG 49. According to this embodiment, the TEG 49 may be mounted as a “button” or a series of “buttons” in a garment 55 (like in US 2006/0000502), see also FIG. 22. The separate units 49 may be interconnected electrically with each other. The hot plate 37 and the cold plate 38 or the radiator 48 can be made flexible for convenience of the wearer and also for decreasing the mechanical shocks when wearing the TEG 49 or during laundry of the garment 55. The hot plate 37 may preferably be larger than the outer size of the thermopile unit 50, the outer size of the thermopile unit 50 being determined in a plane parallel to the hot plate 37, preferably at least twice as large, more preferred at least three times as large, to satisfy the matching conditions described herein and to provide low thermal resistance of the air in between the TEG 49 and the skin in a standard case when the garment 55 is not tight. Tightening bands or threads, preferably elastic tightening bands or threads can optionally also be added to the clothes for better physical contact and therefore also better thermal contact to the skin. The shown example of the device contains thermally isolating pillars 61 or an encapsulating wall 61 on the perimeter of the cold plate 38. The inner volume in between the plates 37 and 38 can be, but does not need to be, completely filled with thermally isolating material other than air, e.g. a nanoporous material. A part of the inner volume may also be used for the accompanying electronic module for power conditioning, energy storage and other useful functions depending on the specificity of the application, e.g. for sensor nodes.

In case a person wears several pieces of garment on top of each other, heat transferring structures 70 like in the example shown in FIG. 42 could be implemented in the layers of the cloth worn under/above the garment layer with the TEG 49. The device represents in this case two or more components separately fabricated in two or more pieces of the garment. The TEG 49 can be, of course, implemented into any of the garment layers. The quantity, size and spread of the heat transferring structures 70 in the cloth may preferably guarantee proper thermal contacting with the TEG 49. This may mean not only a physical contact but also a small distance in between the heat transferring structures and the TEG 49, which still provides reasonable performance of the TEG 49. Magnetic clamping of the heat transferring structures 70 to the TEG 49 or between heat transferring structures 70 in different garment layers 55 can be implemented, see, e.g., US 2006/0000502. The heat transferring structures 70 can be made of metal or any other suitable materials with high thermal conductivity, including flexible materials. The zones of the garment 55 where the heat transfer is needed may alternatively also be subject of locally introducing heat-conductive threads or yarns, e.g. metallic threads, instead of using heat transferring structures 70 as shown in FIG. 42.

1. A thermoelectric generator for connection between a heat source and a heat sink, the thermoelectric generator comprising:
a thermopile unit, said thermopile unit comprising at least one thermopile stage, each thermopile stage comprising a number of thermocouples each having a couple of thermocouple legs, the thermocouple legs being provided in between a hot junction plane and a cold junction plane;
wherein the number of thermocouples is such that the thermal resistance (R_{TEG}) of the thermoelectric generator between a hot junction plane comprising the hottest junctions and a cold junction plane comprising the coldest junctions does not deviate more than 50%, preferably not more than 20%, more preferred not more than 10%, still more preferred not more than 5% from the thermal resistance of the ambient (R_{amb}), being the sum of the thermal resistance of the heat source, the thermal resistance of the heat sink and the thermal resistance of all parts of the thermoelectric generator serially coupled to the at least one thermopile stage, multiplied by the parasitic thermal resistance (R_{TEG,0}) between the hot junction plane comprising the hottest junctions and the cold junction plane comprising the coldest junctions for a same thermoelectric generator but comprising no thermocouples or only one thermocouple leg, this product being divided by the parasitic thermal resistance (R_{TEG,0}) between the hot junction plane comprising the hottest junctions and the cold junction plane comprising the coldest junctions for a same thermoelectric generator but comprising no thermocouples or only one thermocouple leg, summed with twice the thermal resistance of the ambient (R_{amb}).

2. The thermoelectric generator according to claim 1, wherein at least one of said at least one thermopile stage comprises at least one of a first plate thermally connected to the junctions in said hot junction plane and a second plate thermally connected to the junctions in said cold junction plane.

3. The thermoelectric generator according to claim 1, wherein said thermopile unit is thermally connected to and positioned in between a hot plate for connection to the heat source and a cold plate for connection to the heat sink.

4. The thermoelectric generator according to claim 3, said thermoelectric generator furthermore comprising a radiator mounted on or placed instead of the cold plate.

5. The thermoelectric generator according to claim 3, wherein the surface area of the hot plate is larger than the area of the thermopile unit, the area of the thermopile unit being determined in a plane parallel to the hot plate and/or wherein the surface area of the cold plate is larger than the area of the thermopile unit, the area of the thermopile unit being determined in a plane parallel to the cold plate.

6. The thermoelectric generator according to claim 1, further comprising at least one thermally conductive spacer between the at least one thermopile stage and the hot plate and/or the cold plate and/or the radiator and/or between two of the thermopile stages.

7. The thermoelectric generator according to claim 1, wherein the thermopile unit comprises more than one thermopile stage to improve the Rayleigh number or Reynolds number of the heat transfer at the surface of the cold plate or at the surface of the radiator as compared with the same thermoelectric generator with one thermopile stage.

8. The thermoelectric generator according to claim 4, said thermoelectric generator furthermore comprising a thermal reflector positioned in between the hot plate and the cold plate, said thermal reflector covering the hot plate, the cold plate, the radiator, the first plate and/or the second plate and being thermally isolated therefrom.

9. The thermoelectric generator according to claim 1, wherein said thermocouples are micromachined thermocouples.

10. The thermoelectric generator according to claim 1, wherein said thermocouples are positioned on a polymer tape or on a membrane, or wherein thin/thick-film thermocouples without a substrate are used.

11. The thermoelectric generator according to claim 4, wherein at least one of said at least one thermopile stage comprises a thermally conductive structure forming a thermal interconnection between the thermocouple legs and at least one of the cold plate, the hot plate, and the radiator, said thermally conductive structure comprising a thin/thick film of thermally conductive material or a substrate material.

12. The thermoelectric generator according to claim 1, wherein said thermoelectric generator is filled at least partially with thermally isolating material.

13. The thermoelectric generator according to claim 4, said thermoelectric generator furthermore comprising at least one heat-spreading chip between the at least one thermopile stage and the hot plate and/or the cold plate and/or the radiator and/or between two of the thermopile stages.

14. The thermoelectric generator according to claim 4, wherein the inner volume of said thermoelectric generator is encapsulated on its perimeter between the hot plate and the cold plate or the radiator, using a layer of thermally isolating material.

15. The thermoelectric generator according to claim 14 wherein the volume between the hot plate and the cold plate or the radiator is filled with a gas having lower thermal conductivity than air or which is at a pressure that is lower than the atmospheric pressure.

16. The thermoelectric generator according to claim 8, wherein the inner surface of said hot plate or the inner surface of said thermal reflector, being the surface not facing the heat source, has low emissivity, preferably lower than 20%, more preferred lower than 10%, in the infrared region, and wherein the inner surface of said cold plate or the inner surface of said radiator, being the surface not facing the heat sink, has high emissivity, preferably higher than 90%, more preferred higher than 95%, in the infrared region.

17. A method for designing a thermoelectric generator for connection between a heat source and a heat sink and with a limited heat flow through the thermoelectric generator and a non-constant temperature difference between the heat source and the heat sink, the thermoelectric generator comprising a thermopile unit, said thermopile unit comprising at least one thermopile stage, each thermopile stage comprising a number of thermocouples each having a couple of thermocouple legs, the thermocouple legs being provided in between a hot junction plane and a cold junction plane, the method comprising:
determining the thermal resistance (R_{TEG}) of the thermoelectric generator between the hot junction plane comprising the hottest junctions and the cold junction plane comprising the coldest junctions as a function of the number of thermocouples;
determining the sum (R_{amb}) of the thermal resistance of the heat source, the thermal resistance of the heat sink and the thermal resistance of all parts of the thermoelectric generator serially coupled to the at least one thermopile stage, as a function of the number of thermocouples;
determining the parasitic thermal resistance (R_{TEG,0}) between the hot junction plane comprising the hottest junctions and the cold junction plane comprising the coldest junctions for a same thermoelectric generator but comprising no thermocouples or only one thermocouple leg;
dividing the product of R_{amb} and R_{TEG,0} by the sum of R_{TEG,0} and twice R_{amb}, resulting in a thermal resistance value; and
adapting the number of thermocouples such that the thermal resistance (R_{TEG}) of the thermoelectric generator between the hot junction plane comprising the hottest junctions and the cold junction plane comprising the coldest junctions does not deviate more than 50%, preferably not more than 20%, more preferred not more than 10%, still more preferred not more than 5% from said thermal resistance value.

18. The method for designing a thermoelectric generator according to claim 17, wherein said thermopile unit is thermally connected to and positioned in between a hot plate for connection to the heat source and a cold plate for connection to the heat sink.

19. The method for designing a thermoelectric generator according to claim 18, wherein the thermoelectric generator comprises a radiator mounted on or placed instead of the cold plate.

20. The method for designing a thermoelectric generator according to claim 19, furthermore comprising varying the shape and/or the size of at least one of the hot plate and the cold plate and the radiator.

21. The method for designing a thermoelectric generator according to claim 19, wherein the thermoelectric generator comprises at least one thermally conductive spacer in between the at least one thermopile stage and the hot plate and/or the cold plate and/or the radiator and/or between two of the thermopile stages.

22. A computer program product for executing a method for designing a thermoelectric generator according to claim 17.

23. A machine readable data storage device storing the computer program product of claim 22.

24. Transmission of the computer program product of claim 22 over a local or wide area telecommunications network.

25. The use of the thermoelectric generator according to claim 1, wherein said heat source is an animal, a human being, a clothed human being or ambient air and wherein said heat sink is ambient air, an animal, a human being or a clothed human being.

26. The use of the thermoelectric generator according to claim 1, wherein said heat source is a space object or an artificial space object and wherein said heat sink is interplanetary space, a space object or an artificial space object.

27. The use of the thermoelectric generator according to claim 1, wherein said heat source is a distant radiating object or a plurality of distant radiating objects like space objects or ambient objects on earth.
